(19) United States
(12) Patent Application Publication
(10) Pub. No.: US 2026/0269809 A1
(43) Pub. Date: Sep. 10, 2026

(54) SURFACE ACOUSTIC WAVE RESONATOR, SURFACE ACOUSTIC WAVE FILTER, AND MULTIPLEXER

(71) Applicant: Murata Manufacturing Co., Ltd., Nagaokakyo-shi (JP)

(72) Inventors: Issei KIMURA, Nagaokakyo-shi (JP); Kentaro NAKAMURA, Nagaokakyo-shi (JP); Katsuya DAIMON, Nagaokakyo-shi (JP); Yuta ISHII, Nagaokakyo-shi (JP); Takashi OGAMI, Nagaokakyo-shi (JP)

(21) Appl. No.: 19/663,991

(22) Filed: Apr. 30, 2026

Related U.S. Application Data
(63) Continuation of application No. PCT/JP2024/038627, filed on Oct. 30, 2024.

(30) Foreign Application Priority Data
Nov. 1, 2023 (JP) 2023-187578

(51) Int. Cl. H03H 9/25; H03H 9/145; H03H 9/64

(52) U.S. Cl. CPC H03H 9/25; H03H 9/14541; H03H 9/6483

(57) ABSTRACT

A surface acoustic wave resonator includes an electrode on a substrate and including an IDT electrode and load layers spaced apart from each other on or in the substrate and including a dielectric. Each of the load layers at least partially overlaps at least one electrode finger in plan view of the substrate. A number of electrode fingers overlapping the load layers located in first and third sub-regions are each larger than a number of electrode fingers overlapping the plurality of load layers located in a second sub-region. The load layers include two or more load layers overlapping the electrode fingers in the first sub-region and two or more load layers overlapping the electrode fingers in the third sub-region.

### CROSS REFERENCE TO RELATED APPLICATIONS

This application claims the benefit of priority to Japanese Patent Application No. 2023-187578 filed on Nov. 1, 2023 and is a Continuation Application of PCT Application No. PCT/JP2024/038627 filed on Oct. 30, 2024. The entire contents of each application are hereby incorporated herein by reference.

### BACKGROUND OF THE INVENTION

### 1. Field of the Invention

The present invention relates to surface acoustic wave resonators, surface acoustic wave filters, and multiplexers.

### 2. Description of the Related Art

International Publication No. WO 2012/086639 discloses a surface acoustic wave filter that can improve a quality factor (Q factor), which is an index representing sharpness of a peak of resonance, by using a substrate including a multilayer body including a high acoustic velocity support substrate, a low acoustic velocity layer, and a piezoelectric layer.

However, further improvement in the Q factor is desired in conventional surface acoustic wave filters.

### SUMMARY OF THE INVENTION

Example embodiments of the present invention provide surface acoustic wave resonators, surface acoustic wave filters, and multiplexers each with an improved Q factor.

A surface acoustic wave resonator according to an example embodiment of the present invention includes a substrate including a piezoelectric layer, at least one electrode on the substrate and including an IDT electrode, and a plurality of first load layers spaced apart from each other on the substrate or in the substrate and including a dielectric. The at least one electrode includes a plurality of electrode fingers arranged along a first axis on the substrate and each extending along a second axis perpendicular or substantially perpendicular to the first axis. Each of the plurality of first load layers at least partially overlaps at least one corresponding electrode finger in plan view of the substrate. A number of electrode fingers overlapping the plurality of first load layers among the plurality of electrode fingers in a first sub-region and a number of electrode fingers overlapping the plurality of first load layers among the plurality of electrode fingers in a third sub-region are each larger than a number of electrode fingers overlapping the plurality of first load layers among the plurality of electrode fingers in a second sub-region. The first sub-region, the second sub-region, and the third sub-region are obtained by equally dividing, in a direction of the first axis, a region in which the plurality of electrode fingers are located on the substrate. The second sub-region is located between the first sub-region and the third sub-region. The plurality of first load layers include two or more first load layers overlapping the electrode fingers in the first sub-region and two or more first load layers overlapping the electrode fingers in the third sub-region.

A surface acoustic wave filter according to an example embodiment of the present invention includes at least one series-arm resonator and at least one parallel-arm resonator. At least one of the at least one series-arm resonator and the at least one parallel-arm resonator are each defined by a surface acoustic wave resonator according to an example embodiment of the present invention.

A multiplexer according to an example embodiment of the present invention includes a transmission filter connected between an antenna connection terminal and a PA connection terminal and including a pass band including a transmission band of a predetermined band and a reception filter connected between the antenna connection terminal and an LNA connection terminal and including a pass band including a reception band of the predetermined band. At least one of the transmission filter or the reception filter is defined by a surface acoustic wave filter according to an example embodiment of the present invention.

A surface acoustic wave resonator according to an example embodiment of the present invention includes a substrate including a piezoelectric layer, at least one electrode on the substrate and including an IDT electrode, and a dielectric film on the at least one electrode. The at least one electrode includes a plurality of electrode fingers arranged along a first axis on the substrate and each extending along a second axis perpendicular or substantially perpendicular to the first axis. An average of a thickness of the dielectric film on an electrode finger in a first sub-region and an average of a thickness of the dielectric film on an electrode finger in a third sub-region are each larger than an average of a thickness of the dielectric film on an electrode finger in a second sub-region. The first sub-region, the second sub-region, and the third sub-region are obtained by equally dividing, in a direction of the first axis, a region in which the plurality of electrode fingers are located on the substrate. The second sub-region is located between the first sub-region and the third sub-region.

According to example embodiments of the present invention, surface acoustic wave resonators, surface acoustic wave filters, or multiplexers each with an improved Q factor are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a surface acoustic wave resonator according to example embodiment 1 of the present invention.

FIG. 2 is a cross-sectional view of the surface acoustic wave resonator according to example embodiment 1 of the present invention.

FIG. 3 is a partial cross-sectional view of the surface acoustic wave resonator according to example embodiment 1 of the present invention.

FIG. 4 is a partial cross-sectional view of the surface acoustic wave resonator according to example embodiment 1 of the present invention.

FIG. 5 is a plan view of a plurality of electrodes and a plurality of load layers according to example embodiment 1 of the present invention.

FIG. 6 is a graph indicating frequency characteristics of a Q factor of the surface acoustic wave resonators according to example 1 and comparative example 1.

FIG. 7 is a graph indicating resonance characteristics of the surface acoustic wave resonators according to example 1 and comparative example 2.

FIG. 8 is a graph indicating resonance characteristics of the surface acoustic wave resonators according to example 1 and comparative example 3.

FIG. 9 is a graph indicating frequency characteristics of the Q factor of the surface acoustic wave resonators according to example 2 and comparative example 4.

FIG. 10 is a cross-sectional view of the surface acoustic wave resonator according to modification 1 of example embodiment 1 of the present invention.

FIG. 11 is a plan view of the plurality of electrodes and a plurality of load layers according to modification 2 of example embodiment 1 of the present invention.

FIG. 12 is a plan view of an electrode and a plurality of load layers according to modification 3 of example embodiment 1 of the present invention.

FIG. 13 is a plan view of the plurality of electrodes and a plurality of load layers according to modification 4 of example embodiment 1 of the present invention.

FIG. 14 is a partial cross-sectional view of the surface acoustic wave resonator according to modification 4 of example embodiment 1 of the present invention.

FIG. 15 is a plan view of the surface acoustic wave resonator according to modification 5 of example embodiment 1 of the present invention.

FIG. 16 is a cross-sectional view of the surface acoustic wave resonator according to modification 5 of example embodiment 1 of the present invention.

FIG. 17 is a circuit configuration diagram of a surface acoustic wave filter according to example embodiment 2 of the present invention.

FIG. 18 is a plan view of the surface acoustic wave filter according to example embodiment 2 of the present invention.

FIG. 19 is a circuit configuration diagram of a multiplexer according to example embodiment 3 of the present invention.

### DETAILED DESCRIPTION OF THE EXAMPLE EMBODIMENTS

Example embodiments of the present invention are described in detail below with reference to the drawings. The example embodiments described below each show a comprehensive or specific example. Numerical values, shapes, materials, components, arrangements of components, connection configurations, and the like shown in the following example embodiments are merely examples and are not intended to limit the scope of the present invention.

The respective drawings are schematic diagrams in which emphasis, omission, or adjustment of a proportion is made as appropriate to show example embodiments of the present invention, and are not necessarily depicted strictly. Shapes, positional relationships, and proportions in the drawings are sometimes different from actual ones. In the respective drawings, the same or substantially the same components are denoted by the same reference numerals, and redundant description is sometimes omitted or simplified.

In the following drawings, an x-axis and a y-axis are axes orthogonal or substantially orthogonal to each other on a plane parallel or substantially parallel to a main surface of a substrate. Specifically, the x-axis is an axis along which a plurality of electrode fingers disposed on the substrate are arranged, and is sometimes also referred to as a propagation direction of a surface acoustic wave. The y-axis is an axis along which each of the plurality of electrode fingers disposed on the substrate extends. Further, a z-axis is an axis perpendicular or substantially perpendicular to the main surface of the substrate. A positive direction thereof indicates an upward direction, and a negative direction thereof indicates a downward direction.

In the present disclosure, the term “connected” includes not only a case where components are directly connected by a connection terminal and/or a wiring conductor but also a case where components are electrically connected through another circuit element. The term “directly connected” means that components are directly connected by a connection terminal and/or a wiring conductor without another circuit element interposed therebetween. The expression “C is connected between A and B” means that one end of C is connected to A and the other end of C is connected to B, and means that C is disposed in series in a path connecting A and B. The expression “a path connecting A and B” means a path including a conductor that electrically connects A to B.

The term “terminal” means a point at which a conductor in an element terminates. When the impedance of a conductor between elements is sufficiently low, a terminal can be interpreted not only as a single point but also as any point on the conductor between the elements or the entire conductor.

The expression “a pass band of a filter” refers to a portion of a frequency spectrum transmitted by the filter, and is defined as a frequency band in which output power is not attenuated by about 3 dB or more relative to maximum output power, for example. Accordingly, a high frequency end and a low frequency end of a pass band of a band pass filter are specified as a higher frequency and a lower frequency of two points at which output power is attenuated by about 3 dB relative to maximum output power, for example.

The term “reception band” means a frequency band used for reception in a communication device, and the term “transmission band” means a frequency band used for transmission in the communication device. For example, in a band for frequency division duplex (FDD), mutually different frequency bands (uplink band and downlink band) are used as the transmission band and the reception band. For example, in a band for time division duplex (TDD), the same frequency band is used as the transmission band and the reception band.

The expression “plan view of the substrate” means viewing an object by orthogonally projecting the object onto an xy-plane in the negative direction of the z-axis. The expression “A overlaps B in plan view” means that a region of A orthogonally projected onto an xy-plane overlaps a region of B orthogonally projected onto the xy-plane.

Further, terms indicating relationships between elements, such as “parallel” and “perpendicular,” terms indicating shapes of elements, such as “rectangular,” and numerical ranges do not represent only strict meanings, but mean that the terms include substantially equivalent ranges, for example, ranges including an error of approximately several percent.

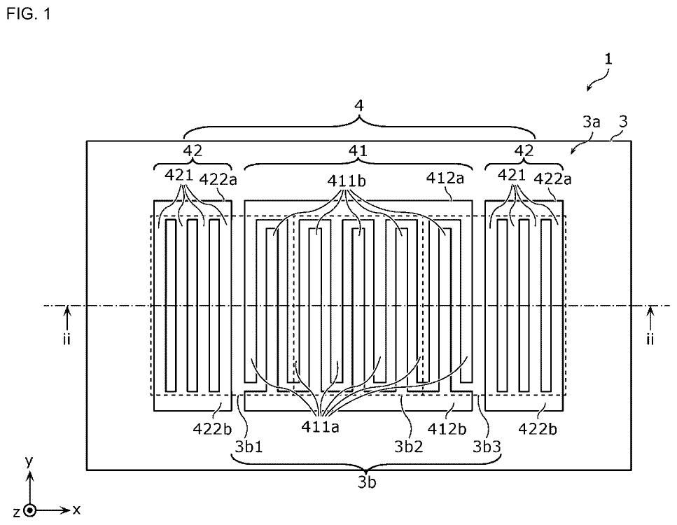

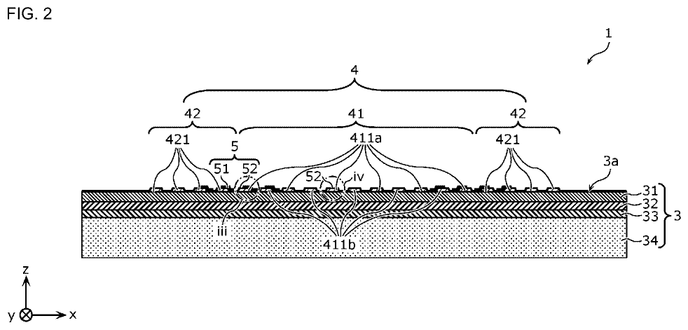

First, an overall configuration of a surface acoustic wave resonator 1 according to example embodiment 1 of the present invention is specifically described with reference to FIGS. 1 and 2. FIGS. 1 and 2 are a plan view and a cross-sectional view of the surface acoustic wave resonator 1 according to the present example embodiment. The cross section of the surface acoustic wave resonator 1 in FIG. 2 is a cross section taken along line ii-ii in FIG. 1.

FIGS. 1 and 2 are diagrams for explaining a typical configuration of the surface acoustic wave resonator 1, and the configuration of the surface acoustic wave resonator 1 is not limited to the configuration depicted in FIGS. 1 and 2. Accordingly, a description of the surface acoustic wave resonator 1 provided below should not be construed in a limited manner.

The surface acoustic wave resonator 1 includes a substrate 3, a plurality of electrodes 4, and a dielectric film 5. The substrate 3 includes a piezoelectric layer 31, a low acoustic velocity layer 32, a high acoustic velocity layer 33, and a support substrate 34.

The piezoelectric layer 31 is a layer that is laminated on the low acoustic velocity layer 32 and has piezoelectricity, and can propagate a surface acoustic wave (SAW). The plurality of electrodes 4 are disposed on the piezoelectric layer 31. As a material of the piezoelectric layer 31, for example, a piezoelectric single crystal or piezoelectric ceramics of lithium tantalate (LiTaO₃), lithium niobate (LiNbO₃), aluminum nitride, or zinc oxide can be used. The electrodes 4 may be disposed on one main surface 31a of the piezoelectric layer 31 including the main surfaces 31a and 31b opposed to each other, or may be disposed on the other main surface 31b.

The low acoustic velocity layer 32 is laminated on the high acoustic velocity layer 33, and is disposed between the piezoelectric layer 31 and the high acoustic velocity layer 33. The acoustic velocity of a bulk wave propagating in the low acoustic velocity layer 32 is lower than that of acoustic waves such as a surface acoustic wave and a boundary wave propagating in the piezoelectric layer 31. As a material of the low acoustic velocity layer 32, for example, the following materials can be used: a dielectric such as silicon dioxide, glass, silicon oxynitride, lithium oxide, tantalum oxide, or a compound obtained by adding fluorine, carbon, or boron to silicon oxide, or any combination of these materials. The material of the low acoustic velocity layer 32 is not limited to these materials.

The high acoustic velocity layer 33 is laminated on the support substrate 34, and is disposed between the low acoustic velocity layer 32 and the support substrate 34. The high acoustic velocity layer 33 can confine a surface acoustic wave generated by the electrodes 4 in a portion in which the piezoelectric layer 31 and the low acoustic velocity layer 32 are laminated, and can reduce or prevent the surface acoustic wave from leaking to a layer below the high acoustic velocity layer 33. The acoustic velocity of a bulk wave propagating in the high acoustic velocity layer 33 is higher than that of acoustic waves such as a surface acoustic wave and a boundary wave propagating in the piezoelectric layer 31. As a material of the high acoustic velocity layer 33, for example, the following materials can be used: a piezoelectric material such as silicon nitride, aluminum nitride, lithium tantalate, lithium niobate, or quartz, a ceramic such as alumina, sapphire, magnesia, silicon carbide, zirconia, cordierite, mullite, steatite, or forsterite, a dielectric such as diamond or glass, a semiconductor such as silicon or gallium nitride, a resin, or any combination of these materials. The material of the high acoustic velocity layer 33 is not limited to these materials.

The support substrate 34 can support the piezoelectric layer 31, the low acoustic velocity layer 32, and the high acoustic velocity layer 33. As a material of the support substrate 34, for example, the following materials can be used: a piezoelectric material such as silicon nitride, aluminum nitride, lithium tantalate, lithium niobate, or quartz, a ceramic such as alumina, sapphire, magnesia, silicon nitride, silicon carbide, zirconia, cordierite, mullite, steatite, or forsterite, a dielectric such as diamond or glass, a semiconductor such as silicon or gallium nitride, a resin, or any combination of these materials. The material of the support substrate 34 is not limited to these materials.

The high acoustic velocity layer 33 and the support substrate 34 may be integrated as a single high acoustic velocity support substrate. As a material of the high acoustic velocity support substrate, for example, the following materials can be used: a piezoelectric material such as aluminum nitride, lithium tantalate, lithium niobate, or quartz, a ceramic such as alumina, sapphire, magnesia, silicon nitride, silicon carbide, zirconia, cordierite, mullite, steatite, forsterite, a spinel group material, or SiALON, a dielectric such as aluminum oxide, silicon oxynitride, diamond-like carbon (DLC), or diamond, a semiconductor such as silicon; or any combination of these materials. The above-described spinel group includes, for example, aluminum compounds including oxygen and one or more of magnesium, iron, zinc, manganese, or the like. Specific examples thereof include spinel (MgAl₂O₄), hercynite (FeAl₂O₄), gahnite (ZnAl₂O₄), or galaxite (MnAl₂O₄).

The plurality of electrodes 4 are an example of at least one first electrode. The electrodes 4 are disposed on the substrate 3, and include an interdigital transducer (IDT) electrode 41 and a pair of reflector electrodes 42.

The IDT electrode 41 is an example of a first IDT electrode. The IDT electrode 41 includes two interdigitated comb-shaped electrodes disposed on the piezoelectric layer 31, and can convert an electrical signal to a surface acoustic wave and inversely convert a surface acoustic wave to an electrical signal. The IDT electrode 41 includes a plurality of electrode fingers 411a and 411b and busbar electrodes 412a and 412b.

The plurality of electrode fingers 411a and 411b are an example of a plurality of first electrode fingers. The electrode fingers 411a and 411b are alternately arranged along the x-axis (first axis), and each extend along the y-axis (second axis). One end of each of the electrode fingers 411a is connected to the busbar electrode 412a, and the electrode fingers 411a extend from the busbar electrode 412a in a negative direction of the y-axis. One end of each of the electrode fingers 411b is connected to the busbar electrode 412b, and the electrode fingers 411b extend from the busbar electrode 412b in a positive direction of the y-axis. The electrode fingers 411a and 411b are not required to be disposed alternately one by one. For example, sets of two or more electrode fingers 411a and sets of two or more electrode fingers 411b may be alternately disposed.

The busbar electrode 412a extends along the x-axis, and is connected to the one end of each of the electrode fingers 411a. The busbar electrode 412a is disposed in parallel with the busbar electrode 412b, and is spaced apart from the busbar electrode 412b in the positive direction of the y-axis.

The busbar electrode 412b extends along the x-axis, and is connected to the one end of each of the electrode fingers 411b. The busbar electrode 412b is disposed in parallel with the busbar electrode 412a, and is spaced apart from the busbar electrode 412a in the negative direction of the y-axis.

The pair of reflector electrodes 42 are an example of a pair of first reflector electrodes, and are disposed on both sides of the IDT electrode 41 in the x-axis direction in order to confine a predetermined high frequency signal resonating in the IDT electrode 41 within the IDT electrode 41. That is, the IDT electrode 41 is disposed between the pair of reflector electrodes 42 in the x-axis direction. Each of the pair of reflector electrodes 42 includes a plurality of electrode fingers 421 and busbar electrodes 422a and 422b. The plurality of electrode fingers 421 are an example of the plurality of first electrode fingers. The electrode fingers 421 are arranged along the x-axis, and each extend along the y-axis. Both ends of the electrode fingers 421 are connected to the busbar electrodes 422a and 422b. The busbar electrode 422a extends along the x-axis, and is connected to one end of each of the electrode fingers 421. The busbar electrode 422b extends along the x-axis. The busbar electrode 422b is disposed in parallel with and opposite the busbar electrode 422a, and is connected to the other end of each of the electrode fingers 421.

As materials of the IDT electrode 41 and the pair of reflector electrodes 42, for example, aluminum, titanium, gold, silver, copper, platinum, tungsten, molybdenum, ruthenium, or any combination of these materials can be used. The materials of the IDT electrode 41 and the pair of reflector electrodes 42 are not limited to these materials. Further, the materials of the IDT electrode 41 and the pair of reflector electrodes 42 may be different from each other, or may be the same.

The dielectric film 5 is disposed on the substrate 3, and covers the substrate 3 and the plurality of electrodes 4. The dielectric film 5 includes a plurality of load layers 51 and a protective film 52.

The plurality of load layers 51 are an example of a plurality of first load layers, and include a dielectric. In the present example embodiment, the plurality of load layers 51 are a plurality of load films (example of a plurality of first load films) spaced apart from each other on the substrate 3. Each of the load layers 51 at least partially overlaps at least one corresponding electrode finger in plan view of the substrate 3. Thus, the load layers 51 can add mass to some of the electrode fingers 411a, 411b, and 421.

As a material of the load layers 51, for example, a dielectric material is used. Specifically, for example, it is possible to use tantalum pentoxide (Ta₂O₅), niobium pentoxide (Nb₂O₅), tungsten oxide (VI) (WO₃), silicon nitride (SiN), titanium oxide (IV) (TiO₂), cerium oxide (IV) (CeO₂), hafnium oxide (IV) (HfO₂), ytterbium oxide (III) (Yb₂O₃), silicon dioxide, alumina, or any combination of these materials. The material of the load layers 51 is not limited to these materials. The load layers 51 can be made thinner by using a dielectric material having a density higher than that of the protective film 52 as the material of the load layers 51. The load layers 51 may include materials different from each other.

The protective film 52 is disposed on the substrate 3, and covers the IDT electrode 41, the reflector electrodes 42, and the main surface 3a of the substrate 3. As a material of the protective film 52, for example, a dielectric material is used. Specifically, for example, it is possible to use silicon dioxide, silicon nitride, alumina, or any combination of these materials. The material of the protective film 52 is not limited to these materials. The material of the protective film 52 may be different from the material of the load layers 51, or may be the same as the material of the load layers 51. The protective film 52 is not required to be included in the dielectric film 5, and may be omitted from the surface acoustic wave resonator 1.

An electrode finger region 3b on the main surface 3a of the substrate 3 is a region in which the plurality of electrode fingers 411a, 411b, and 421 are disposed, and is equally divided into a first sub-region 3b1, a second sub-region 3b2, and a third sub-region 3b3 in the x-axis direction. The electrode finger region 3b is defined as a rectangular region that encloses the plurality of electrode fingers 411a, 411b, and 421 with a minimum area. In FIG. 1, the first sub-region 3b1, the second sub-region 3b2, and the third sub-region 3b3 include a left partial region, a central partial region, and a right partial region, respectively, of the electrode finger region 3b. The second sub-region 3b2 is located between the first sub-region 3b1 and the third sub-region 3b3.

The configuration of the surface acoustic wave resonator 1 is not limited to the configuration depicted in FIGS. 1 and 2. For example, the surface acoustic wave resonator 1 may be a longitudinally coupled surface acoustic wave resonator. Further, the substrate 3 of the surface acoustic wave resonator 1 is not required to include the low acoustic velocity layer 32 and the high acoustic velocity layer 33.

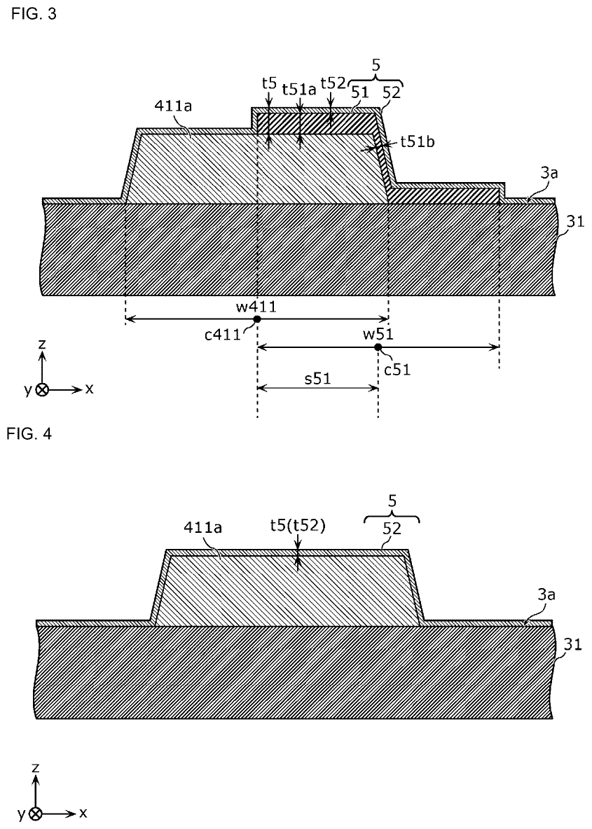

Cross-sectional configurations of the electrode finger 411a and the dielectric film 5 are described with reference to FIGS. 3 and 4. Although the electrode finger 411a is described below, the other electrode fingers 411b and 421 are the same as or similar to the electrode finger 411a, and thus description thereof is omitted.

FIGS. 3 and 4 are partial cross-sectional views of the surface acoustic wave resonator 1 according to the present example embodiment. Specifically, FIG. 3 is an enlarged view of portion iii in FIG. 2, and FIG. 4 is an enlarged view of portion iv in FIG. 2.

FIGS. 3 and 4 are diagrams for explaining typical configurations of the electrode finger 411a and the dielectric film 5, and the configurations of the electrode finger 411a and the dielectric film 5 are not limited to the configurations depicted in FIGS. 3 and 4. Accordingly, a description of the electrode finger 411a and the dielectric film 5 provided below should not be construed in a limited manner.

In FIG. 3, the electrode finger 411a is covered with the load layer 51 and the protective film 52. Specifically, one portion (right portion) of the electrode finger 411a is covered with the load layer 51 and the protective film 52, and the other portion (left portion) of the electrode finger 411a is not covered with the load layer 51 but covered with the protective film 52. The load layer 51 is laminated on the one portion of the electrode finger 411a and the piezoelectric layer 31, and the protective film 52 is laminated on the other portion of the electrode finger 411a, the piezoelectric layer 31, and the load layer 51. The load layer 51 may be laminated on the protective film 52.

A midpoint c51 of a length of the load layer 51 along the x-axis (width w51 of the load layer 51) is shifted by a shift amount s51 in a positive direction of the x-axis of the IDT electrode 41 with respect to a midpoint c411 of a length of the electrode finger 411a along the x-axis (width w411 of the electrode finger 411a). That is, the load layer 51 is shifted along the x-axis toward the center of the IDT electrode 41 with respect to the corresponding electrode finger 411a.

Further, a thickness t51a of the load layer 51 on a top surface of the electrode finger 411a is larger than a thickness t51b of the load layer 51 on a side surface of the electrode finger 411a, and is larger than a thickness t52 of the protective film 52. Hereinafter, when the expression “thickness of the load layer on the electrode finger” is simply used, it refers to the thickness of the load layer on the top surface of the electrode finger (thickness t51a in FIG. 3).

In FIG. 4, the electrode finger 411a is not covered with the load layer 51 but is covered with the protective film 52. Accordingly, a thickness t5 (=t52) of the dielectric film 5 on the electrode finger 411a in FIG. 4 is smaller than the thickness t5 (=t51a+t52) of the dielectric film 5 on the electrode finger 411a in FIG. 3.

The thicknesses of the dielectric film 5, the load layer 51 (load film), and the protective film 52 are measured by observing a cut surface of the surface acoustic wave resonator 1 with a scanning electron microscope (SEM), for example. The cut surface of the surface acoustic wave resonator 1 is a cut surface that is perpendicular to the main surface 3a of the substrate 3 and passes through a straight line connecting center points of an intersecting width of the plurality of electrode fingers 411a, 411b, and 421. The intersecting width of the plurality of electrode fingers 411a, 411b, and 421 is a length in a direction (y-axis direction) perpendicular to the propagation direction of a surface acoustic wave (x-axis direction) regarding a region where adjacent electrode fingers intersect when viewed in the propagation direction.

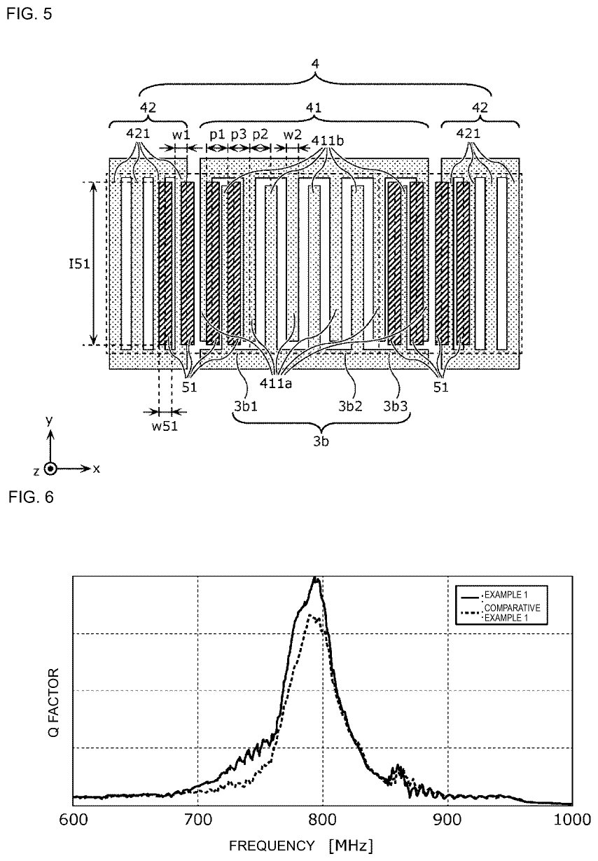

Next, with reference to FIG. 5, a description is provided of a positional relationship between the plurality of electrode fingers 411a, 411b, and 421 and the plurality of load layers 51 in plan view of the substrate 3.

FIG. 5 is a plan view of the plurality of electrodes 4 and the plurality of load layers 51 according to the present example embodiment. Specifically, FIG. 5 is a diagram obtained by orthogonally projecting the electrodes 4 and the load layers 51 onto an xy-plane.

FIG. 5 is a diagram for explaining a typical positional relationship between the plurality of electrodes 4 and the plurality of load layers 51, and the positional relationship between the plurality of electrodes 4 and the plurality of load layers 51 is not limited to the positional relationship depicted in FIG. 5. Accordingly, a description of the plurality of electrodes 4 and the plurality of load layers 51 provided below should not be construed in a limited manner.

The plurality of load layers 51 correspond to some of the plurality of electrode fingers 411a, 411b, and 421 in a one-to-one relationship. Each of the load layers 51 has a shape (rectangular shape) the same as or similar to that of a corresponding one of the electrode fingers 411a, 411b, or 421, and extends along the y-axis. Each of the load layers 51 partially overlaps the corresponding one of the electrode fingers 411a, 411b, or 421 in plan view of the substrate 3. Specifically, one portion of each of the load layers 51 overlaps a portion of the corresponding one of the electrode fingers 411a, 411b, or 421, and the other portion of each of the load layers 51 overlaps a portion of a gap between the corresponding one of the electrode fingers 411a, 411b, or 421 and the electrode finger 411a, 411b, or 421 adjacent thereto. Each of the load layers 51 may, not partially but entirely, overlap the corresponding one of the electrode fingers 411a, 411b, or 421 in plan view of the substrate 3. In FIG. 5, in plan view of the substrate 3, the area of the portion where each of the load layers 51 overlaps the corresponding one of the electrode fingers 411a, 411b, or 421 is, for example, approximately half of the total area of each of the load layers 51. However, the present invention is not limited thereto.

Each of the load layers 51 is shifted along the x-axis toward the center of the IDT electrode 41 with respect to the corresponding one of the electrode fingers 411a, 411b, or 421. For example, as depicted in FIG. 3, the midpoint c51 of the length of the load layer 51 along the x-axis (width w51 of the load layer 51) is shifted along the x-axis toward the center of the IDT electrode 41 (in the positive direction of the x-axis) with respect to the midpoint c411 of the length of the electrode finger 411a along the x-axis (width w411 of the electrode finger 411a).

In plan view of the substrate 3, the plurality of load layers 51 partially overlap some of the plurality of electrode fingers 411a and 411b of the IDT electrode 41, and partially overlap some of the plurality of electrode fingers 421 of each of the pair of reflector electrodes 42. Specifically, the plurality of load layers 51 partially overlap the two electrode fingers 411a and 411b closer to a respective one of the pair of reflector electrodes 42 among the plurality of electrode fingers 411a and 411b of the IDT electrode 41. Further, the plurality of load layers 51 partially overlap the two electrode fingers 421 closer to the IDT electrode 41 among the plurality of electrode fingers 421 of each of the pair of reflector electrodes 42.

The number of electrode fingers overlapping the load layers 51 among the electrode fingers 411a, 411b, and 421 disposed in the first sub-region 3b1 (four in FIG. 5) is greater than the number of electrode fingers overlapping the load layers 51 among the electrode fingers 411a and 411b disposed in the second sub-region 3b2 (zero in FIG. 5). Similarly, the number of electrode fingers overlapping the load layers 51 among the electrode fingers 411a, 411b, and 421 disposed in the third sub-region 3b3 (four in FIG. 5) is greater than the number of electrode fingers overlapping the load layers 51 among the electrode fingers 411a and 411b disposed in the second sub-region 3b2 (zero in FIG. 5).

Further, the value of the ratio (for example, 4/7 in FIG. 5) of the number of electrode fingers overlapping the load layers 51 (for example, four in FIG. 5) to the total number of electrode fingers 411a, 411b, and 421 disposed in the first sub-region 3b1 (for example, seven in FIG. 5) is larger than the value of the ratio (for example, 0/7 in FIG. 5) of the number of electrode fingers overlapping the load layers 51 (for example, zero in FIG. 5) to the total number of electrode fingers 411a and 411b disposed in the second sub-region 3b2 (for example, seven in FIG. 5). Similarly, the value of the ratio (for example, 4/7 in FIG. 5) of the number of electrode fingers overlapping the load layers 51 (for example, four in FIG. 5) to the total number of electrode fingers 411a, 411b, and 421 disposed in the third sub-region 3b3 (for example, seven in FIG. 5) is larger than the value of the ratio (for example, 0/7 in FIG. 5) of the number of electrode fingers overlapping the load layers 51 (for example, zero in FIG. 5) to the total number of electrode fingers 411a and 411b disposed in the second sub-region 3b2 (, for example, seven in FIG. 5).

In this case, the electrode finger disposed across two sub-regions is counted, in each of the two sub-regions, as the electrode finger disposed in the sub-region. For example, in FIG. 5, the electrode finger 411a disposed at a boundary between the first sub-region 3b1 and the second sub-region 3b2 is counted as the electrode finger disposed in the first sub-region 3b1 and is also counted as the electrode finger disposed in the second sub-region 3b2.

The number and arrangement of the electrode fingers overlapping the plurality of load layers 51 are not limited to those in FIG. 5. For example, the load layers 51 may overlap the electrode fingers 411a and/or 411b disposed in the second sub-region 3b2. Further, for example, the load layers 51 may overlap all of the electrode fingers 421 of the pair of reflector electrodes 42. Further, for example, the load layers 51 may partially overlap one or more electrode fingers 421 farther from the IDT electrode 41 among the electrode fingers 421 of each of the pair of reflector electrodes 42.

The plurality of electrode fingers 411a, 411b, and 421 disposed in each of the first sub-region 3b1 and the third sub-region 3b3 overlap not a single load layer 51 but two or more load layers 51. In FIG. 5, the four electrode fingers 411a, 411b, and 421 disposed in each of the first sub-region 3b1 and the third sub-region 3b3 overlap four load layers 51. That is, the plurality of load layers 51 include two or more load layers 51 overlapping two or more electrode fingers disposed in the first sub-region 3b1 and two or more load layers 51 overlapping two or more electrode fingers disposed in the third sub-region 3b3.

The number, shape, and size (length along the x-axis, length along the y-axis, and thickness) of the plurality of load layers 51 can be determined in accordance with required specifications of the surface acoustic wave resonator 1. The number, shape, size, pitch, and duty ratio of the plurality of electrode fingers 411a, 411b, and 421 can also be determined in accordance with required specifications of the surface acoustic wave resonator 1.

For example, the duty ratio of the plurality of electrode fingers 411a, 411b, and 421 is not required to be uniform within the surface acoustic wave resonator 1. For example, the duty ratio (w1/p1) of the plurality of electrode fingers 411a, 411b, and 421 overlapping the plurality of load layers 51 may be different from the duty ratio (w2/p2) of the plurality of electrode fingers 411a and 411b that do not overlap the plurality of load layers 51. The duty ratio of the plurality of electrode fingers is defined as the ratio of an average of the length of the electrode fingers along the x-axis (average width) to an average pitch of the electrode fingers.

Further, for example, the pitch of the plurality of electrode fingers 411a, 411b, and 421 is not required to be uniform within the surface acoustic wave resonator 1. For example, a pitch p3 between the electrode finger overlapping the load layer 51 and the electrode finger that does not overlap the load layer 51 may be different from a pitch p1 of the electrode fingers overlapping the load layer 51, and may be different from a pitch p2 of the electrode fingers that do not overlap the load layer 51. That is, a spacing (pitch p3) between the electrode finger overlapping any of the load layers 51 and the electrode finger that is adjacent to this electrode finger and does not overlap any of the load layers 51 may be different from a spacing (pitch p1) between two electrode fingers that are adjacent to each other and overlap the load layers 51, and may be different from a spacing (pitch p2) between two electrode fingers that are adjacent to each other and do not overlap any of the load layers 51. The spacing between two electrode fingers is defined as the length of a line segment, on a straight line parallel to the x-axis, connecting a midpoint of the length of one of the two electrode fingers along the x-axis and a midpoint of the length of the other of the two electrode fingers along the x-axis.

Further, for example, the duty ratio of the plurality of electrode fingers 411a and 411b that do not overlap the plurality of load layers 51 is not required to be uniform within the surface acoustic wave resonator 1. Further, for example, at least one width w2 of the plurality of electrode fingers 411a and 411b that do not overlap the plurality of load layers 51 may be different from at least one other width w2 of the plurality of electrode fingers 411a and 411b that do not overlap the plurality of load layers 51. Further, for example, a spacing (pitch p2) of at least one set of adjacent electrode fingers among the plurality of electrode fingers 411a and 411b that do not overlap the plurality of load layers 51 may be different from a spacing (pitch p2) of at least one other set of adjacent electrode fingers among the plurality of electrode fingers 411a and 411b that do not overlap the plurality of load layers 51. Further, spacings (pitch p2) of a plurality of sets of adjacent electrode fingers among the plurality of electrode fingers 411a and 411b that do not overlap the plurality of load layers 51 may be different from each other. In this case, spacings (pitch p2) of all sets of adjacent electrode fingers among the plurality of electrode fingers 411a and 411b that do not overlap the plurality of load layers 51 may be different from each other.

With reference to FIGS. 6 to 9, a description is provided of a comparison of characteristics between the surface acoustic wave resonators according to examples 1 and 2 based on example embodiment 1 and surface acoustic wave resonators according to comparative examples 1 to 4.

Specifications of the surface acoustic wave resonator according to example 1 are described in the following (a) to (h).
(a) The support substrate 34 is a silicon substrate having a plane orientation [111]. (b) The high acoustic velocity layer 33 is a silicon nitride (SiN) layer having a thickness of about 300 nm, for example. (c) The low acoustic velocity layer 32 is a silicon dioxide (SiO₂) layer having a thickness of about 673 nm, for example. (d) The piezoelectric layer 31 is a lithium tantalate (LiTaO₃) layer having a thickness of about 1000 nm, and a cut-angle thereof is about 35 degrees, for example. (e) The IDT electrode 41 has a three-layer structure including a titanium (Ti) layer having a thickness of about 60 nm, a copper-aluminum alloy (Al-1% Cu) layer having a thickness of about 380 nm, and a titanium (Ti) layer having a thickness of about 4 nm, for example. The pitch of the IDT electrode 41 is about 2.5μm, and the duty ratio of the IDT electrode 41 is about 0.435, for example. The numbers of electrode fingers 411a and 411b of the IDT electrode 41 are each 81, for example. (f) The number of electrode fingers 421 of each of the pair of reflector electrodes 42 is 10, for example. (g) The load layers 51 are each a tantalum pentoxide (Ta₂O₅) film having a thickness of about 120 nm, for example. The load layers 51 cover each of the electrode fingers 421 of each of the pair of reflector electrodes 42, and cover five electrode fingers 411a and 411b closer to a respective one of the pair of reflector electrodes 42 among the electrode fingers 411a and 411b of the IDT electrode 41. (h) The protective film 52 is a silicon dioxide (SiO₂) film having a thickness of about 50 nm, for example.

Further, specifications of the surface acoustic wave resonator according to example 2 are the same or substantially the same as the specifications of the surface acoustic wave resonator according to the above example 1 regarding (a) to (e) and (h), but (f) and (g) are replaced by (f′) and (g′). (f′) The pair of reflector electrodes 42 are not included. (g′) The load layers 51 are each a tantalum pentoxide (Ta₂O₅) film having a thickness of about 120 nm, for example. The load layers 51 cover ten electrode fingers 411a and 411b closer to a respective one of both ends in the propagation direction (x-axis direction) among the electrode fingers 411a and 411b of the IDT electrode 41.

FIG. 6 is a graph indicating frequency characteristics of a Q factor of the surface acoustic wave resonators according to example 1 and comparative example 1. In FIG. 6, a horizontal axis represents the frequency, and a vertical axis represents the Q factor.

The surface acoustic wave resonator according to comparative example 1 is obtained by removing the load layers 51 from the surface acoustic wave resonator according to example 1. That is, the dielectric film 5 of the surface acoustic wave resonator according to comparative example 1 includes only the protective film 52 and does not include the load layers 51.

As depicted in FIG. 6, the Q factor of the surface acoustic wave resonator according to example 1 is higher than the Q factor of the surface acoustic wave resonator according to comparative example 1. In particular, for example, the Q factor in a frequency range of about 700 MHz to about 800 MHz is improved.

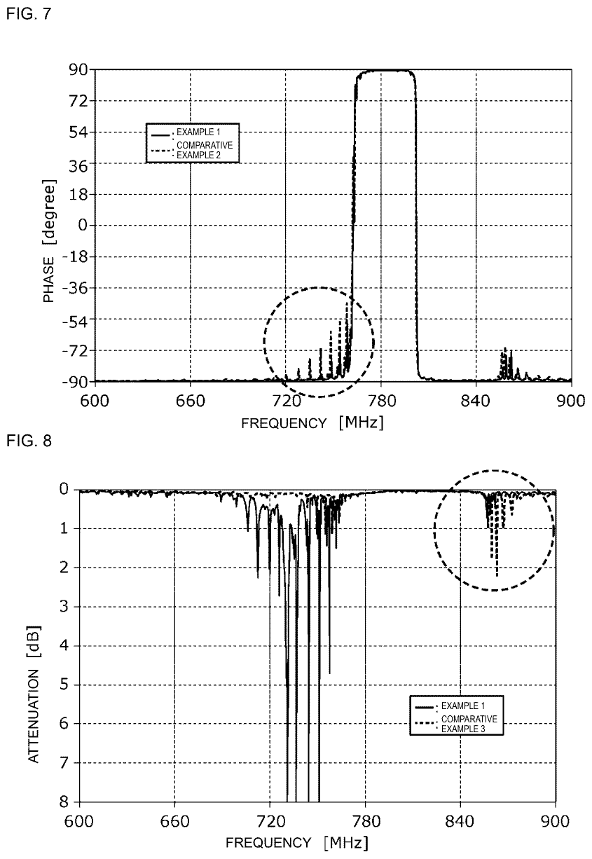

FIG. 7 is a graph indicating resonance characteristics of the surface acoustic wave resonators according to example 1 and comparative example 2. In FIG. 7, a horizontal axis represents the frequency, and a vertical axis represents the phase.

The surface acoustic wave resonator according to comparative example 2 is obtained by setting, to 0, the shift amount between the load layer 51 and the corresponding electrode finger 411a, 411b, or 421 (shift amount s51 in FIG. 3) in the surface acoustic wave resonator according to example 1. That is, in the surface acoustic wave resonator according to comparative example 2, the x-coordinate of the center of the length of the load layer 51 along the x-axis coincides with the x-coordinate of the center of the length of the corresponding electrode finger 411a, 411b, or 421 along the x-axis.

As depicted in FIG. 7, in a frequency range of, for example, about 720 MHz to about 760 MHz in which a longitudinal mode occurs, the surface acoustic wave resonator according to example 1 can reduce or prevent fluctuations in the phase more than the surface acoustic wave resonator according to comparative example 2 (see a region surrounded by a dashed line). That is, the surface acoustic wave resonator according to example 1 can constrain the longitudinal mode and reduce or prevent a ripple attributed to the longitudinal mode more than the surface acoustic wave resonator according to comparative example 2.

FIG. 8 is a graph indicating resonance characteristics of the surface acoustic wave resonators according to example 1 and comparative example 3. In FIG. 8, a horizontal axis represents the frequency, and a vertical axis represents the attenuation.

The surface acoustic wave resonator according to comparative example 3 is obtained by removing the load layers 51 overlapping the electrode fingers 411a and 411b of the IDT electrode 41 from the surface acoustic wave resonator according to example 1. That is, the load layers 51 in the surface acoustic wave resonator according to comparative example 3 overlap only the electrode fingers 421 of the reflector electrodes 42 among the electrode fingers 411a, 411b, and 421 of the IDT electrode 41 and the reflector electrodes 42.

As depicted in FIG. 8, in a frequency range of, for example, about 840 MHz to about 880 MHz in which a stop-band ripple occurs, the surface acoustic wave resonator according to example 1 can reduce or prevent fluctuations in the attenuation more than the surface acoustic wave resonator according to comparative example 3 (see a region surrounded by a dashed line). That is, the surface acoustic wave resonator according to example 1 can reduce or prevent the stop-band ripple more than the surface acoustic wave resonator according to comparative example 3.

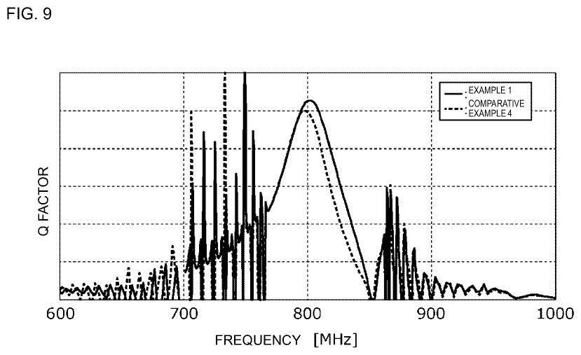

FIG. 9 is a graph indicating frequency characteristics of the Q factor of the surface acoustic wave resonators according to example 2 and comparative example 4. In FIG. 9, a horizontal axis represents the frequency, and a vertical axis represents the Q factor.

The surface acoustic wave resonator according to comparative example 4 is obtained by making the thickness of the load layer 51 on the side surface of the electrode finger (for example, thickness t51b in FIG. 3) equal or substantially equal to the thickness of the load layer 51 on the top surface (for example, thickness t51a in FIG. 3) in the surface acoustic wave resonator according to example 2. That is, the load layers 51 in the surface acoustic wave resonator according to comparative example 4 cover, with the same or substantially the same thickness, the top surfaces and the side surfaces of 20 electrode fingers 411 a and 411 b of the IDT electrode 41.

As depicted in FIG. 9, the Q factor of the surface acoustic wave resonator according to example 2 is improved compared with the surface acoustic wave resonator according to comparative example 4. In particular, the Q factor in a frequency range of 800 to 840 MHz is improved.

As described above, the surface acoustic wave resonator 1 according to the present example embodiment includes the substrate 3 including the piezoelectric layer 31, at least one electrode 4 that is disposed on the substrate 3 and includes the IDT electrode 41, and the plurality of load layers 51 that are spaced apart from each other on the substrate 3 or in the substrate 3 and include, for example, a dielectric. At least one electrode 4 includes the plurality of electrode fingers 411a, 411b, and 421 that are arranged along the x-axis on the substrate 3 and each extend along the y-axis perpendicular to the x-axis. Each of the plurality of load layers 51 at least partially overlaps at least one corresponding electrode finger in plan view of the substrate 3. The number of electrode fingers overlapping the plurality of load layers 51 among the electrode fingers disposed in the first sub-region 3b1 and the number of electrode fingers overlapping the plurality of load layers 51 among the electrode fingers disposed in the third sub-region 3b3 are each larger than the number of electrode fingers overlapping the plurality of load layers 51 among the electrode fingers disposed in the second sub-region 3b2. The first sub-region 3b1, the second sub-region 3b2, and the third sub-region 3b3 are obtained by equally dividing, in the x-axis direction, the electrode finger region 3b in which the plurality of electrode fingers 411a, 411b, and 421 are disposed on the substrate 3. The second sub-region 3b2 is located between the first sub-region 3b1 and the third sub-region 3b3. The plurality of load layers 51 include two or more load layers 51 overlapping the electrode fingers disposed in the first sub-region 3b1 and two or more load layers 51 overlapping the electrode fingers disposed in the third sub-region 3b3.

With this configuration, reflectivity can be increased by adding, by the load layers 51, mass to the electrode fingers 411a, 411b, and 421 disposed in the first sub-region 3b1 and the third sub-region 3b3, and an advantageous effect of confining a surface acoustic wave in the surface acoustic wave resonator 1 can be improved. As a result, as depicted in FIG. 6, the Q factor of the surface acoustic wave resonator 1 can be improved. Further, because the load layers 51 include the dielectric, it becomes easier to ensure a distance between adjacent electrode fingers than in a case where the load layers 51 include a conductor, and a decrease in electric power handling capability can be reduced or prevented.

Further, for example, in the surface acoustic wave resonator 1 according to the present example embodiment, at least one electrode 4 may further include the pair of reflector electrodes 42, and the IDT electrode 41 may be disposed between the pair of reflector electrodes 42.

With this configuration, the advantageous effect of confining a surface acoustic wave in the surface acoustic wave resonator 1 can be further improved by the pair of reflector electrodes 42, and the Q factor of the surface acoustic wave resonator 1 can be further improved.

Further, for example, in the surface acoustic wave resonator 1 according to the present example embodiment, at least one of the plurality of load layers 51 may at least partially overlap at least one corresponding electrode finger of the IDT electrode 41 in plan view of the substrate 3, and at least another one of the plurality of load layers 51 may at least partially overlap at least one corresponding electrode finger of the reflector electrode 42 in plan view of the substrate 3.

With this configuration, the load layers 51 overlap the electrode fingers 411a, 411b, and 421 of both of the IDT electrode 41 and the reflector electrodes 42. Thus, as depicted in FIG. 8, the stop-band ripple can be reduced or prevented compared with the case where the load layers 51 overlap only the electrode fingers 421 of the reflector electrodes 42.

Further, for example, in the surface acoustic wave resonator 1 according to the present example embodiment, the plurality of load layers 51 may correspond to some of the plurality of electrode fingers 411a, 411b, and 421 in a one-to-one relationship.

With this configuration, a positional relationship (for example, area of an overlapping portion) between the load layers 51 and the electrode fingers 411a, 411b, or 421 can be adjusted more finely, and characteristics of the surface acoustic wave resonator 1 can be improved.

Further, for example, in the surface acoustic wave resonator 1 according to the present example embodiment, each of the plurality of load layers 51 may overlap a portion of a corresponding one of the electrode fingers in plan view of the substrate 3.

With this configuration, each of the load layers 51 can be made to overlap a portion of the corresponding electrode finger, and the longitudinal mode can be constrained, and the ripple attributed to the longitudinal mode can be reduced or prevented.

Further, for example, in the surface acoustic wave resonator 1 according to the present example embodiment, the midpoint of the length of each of the plurality of load layers 51 along the x-axis may be shifted along the x-axis toward the center of the IDT electrode 41 with respect to the midpoint of the length of the corresponding electrode finger along the x-axis.

With this configuration, each of the load layers 51 can be shifted toward the center side of the IDT electrode 41 with respect to the corresponding electrode finger. Thus, as depicted in FIG. 7, the longitudinal mode can be constrained, and the ripple attributed to the longitudinal mode can be reduced or prevented.

Further, for example, in the surface acoustic wave resonator 1 according to the present example embodiment, the plurality of load layers 51 may be a plurality of load films disposed on the substrate 3, and the plurality of load films may at least partially cover some of the plurality of electrode fingers 411a, 411b, and 421.

With this configuration, the load films disposed on the substrate 3 can be used as the load layers 51, and the surface acoustic wave resonator 1 can be manufactured comparatively easily compared with a case where the load layers 51 are disposed in the substrate 3.

Further, for example, in the surface acoustic wave resonator 1 according to the present example embodiment, in each of the plurality of load layers 51, the thickness of the load layer 51 on the top surface of a corresponding one of the electrode fingers may be larger than the thickness of the load layer 51 on the side surface of the corresponding one of the electrode fingers.

With this configuration, as depicted in FIG. 9, the Q factor of the surface acoustic wave resonator 1 can be improved.

Further, for example, the surface acoustic wave resonator 1 according to the present example embodiment may further include the protective film 52 that is disposed on the substrate 3 and covers at least a portion of the substrate 3 and the plurality of electrode fingers 411a, 411b, and 421.

With this configuration, the load layers 51 (load films) and the protective film 52 can be disposed on the substrate 3. Thus, in addition to improving the Q factor of the surface acoustic wave resonator 1 by the load layers 51, characteristics (for example, temperature characteristics) of the surface acoustic wave resonator 1 can be improved by the protective film 52.

Further, for example, in the surface acoustic wave resonator 1 according to the present example embodiment, the protective film 52 may be laminated on the plurality of load layers 51.

With this configuration, the protective film 52 is laminated on the load layers 51 (load films). Even with such a structure, the Q factor of the surface acoustic wave resonator 1 can be improved.

Further, for example, in the surface acoustic wave resonator 1 according to the present example embodiment, the plurality of load layers 51 may include a material different from a material of the protective film 52.

With this configuration, a material suitable for each of the load layers 51 and the protective film 52 can be used, and manufacturing of the surface acoustic wave resonator 1 can be facilitated or the Q factor can be further improved.

Further, for example, in the surface acoustic wave resonator 1 according to the present example embodiment, the plurality of load layers 51 may include, for example, tantalum pentoxide, niobium pentoxide, tungsten oxide (VI), silicon nitride, titanium oxide (IV), cerium oxide (IV), hafnium oxide (IV), or ytterbium oxide (III), and the protective film 52 may include, for example, silicon dioxide or silicon nitride.

With this configuration, a material having a density higher than that of the protective film 52 is used as the material of the load layers 51. Thus, the load layers 51 can be made thinner, and manufacturing of the surface acoustic wave resonator 1 can be facilitated.

Further, for example, in the surface acoustic wave resonator 1 according to the present example embodiment, the spacing between an electrode finger overlapping the plurality of load layers 51 and an adjacent electrode finger that does not overlap the plurality of load layers 51 may be different from the spacing between two electrode fingers that are adjacent to each other and overlap the plurality of load layers 51, or the spacing between two electrode fingers that are adjacent to each other and do not overlap the plurality of load layers 51.

With this configuration, the longitudinal mode can be constrained, and reduction or prevention of the ripple attributed to the longitudinal mode is enabled.

Further, for example, in the surface acoustic wave resonator 1 according to the present example embodiment, the duty ratio of two or more electrode fingers overlapping the plurality of load layers 51 may be different from the duty ratio of two or more electrode fingers that do not overlap any of the plurality of load layers 51.

With this configuration, the duty ratio of the electrode fingers can be set in accordance with a relationship with the load layer 51, and the Q factor can be further improved.

Further, for example, in the surface acoustic wave resonator 1 according to the present example embodiment, the pitch of two or more electrode fingers 411a, 411b, and 421 overlapping the plurality of load layers 51 may be different from the pitch of two or more electrode fingers 411a, 411b, and 421 that do not overlap any of the plurality of load layers 51.

With this configuration, the pitch of the electrode fingers can be set in accordance with a relationship with the load layer 51, and the Q factor can be further improved.

Further, for example, in the surface acoustic wave resonator 1 according to the present example embodiment, at least one width of two or more electrode fingers 411a, 411b, and 421 that do not overlap any of the plurality of load layers 51 may be different from at least one other width of the two or more electrode fingers 411a, 411b, and 421 that do not overlap any of the plurality of load layers 51.

With this configuration, the widths of the two or more electrode fingers that do not overlap any of the load layers 51 can be individually set, and the Q factor can be further improved.

Further, for example, in the surface acoustic wave resonator 1 according to the present example embodiment, the spacing of at least one set of adjacent electrode fingers among two or more electrode fingers 411a, 411b, and 421 that do not overlap any of the plurality of load layers 51 may be different from the spacing of at least one other set of adjacent electrode fingers among the two or more electrode fingers 411a, 411b, and 421 that do not overlap any of the plurality of load layers 51.

With this configuration, the spacings of adjacent electrode fingers among the two or more electrode fingers that do not overlap any of the load layers 51 can be individually set, and the Q factor can be further improved.

Further, for example, in the surface acoustic wave resonator 1 according to the present example embodiment, the spacings of a plurality of sets of adjacent electrode fingers among the two or more electrode fingers 411a, 411b, and 421 that do not overlap any of the plurality of load layers 51 may be different from each other.

With this configuration, the spacings of adjacent electrode fingers among the two or more electrode fingers that do not overlap any of the load layers 51 can be individually set, and the Q factor can be further improved.

Further, the surface acoustic wave resonator 1 according to the present example embodiment includes the substrate 3 including the piezoelectric layer 31, at least one electrode 4 that is disposed on the substrate 3 and includes the IDT electrode 41, and the dielectric film 5 disposed on at least one electrode 4. At least one electrode 4 includes the plurality of electrode fingers 411a, 411b, and 421 that are arranged along the x-axis on the substrate 3 and each extend along the y-axis perpendicular to the x-axis. An average of the thickness of the dielectric film 5 on the electrode finger disposed in the first sub-region 3b1 and an average of the thickness of the dielectric film 5 on the electrode finger disposed in the third sub-region 3b3 are each larger than an average of the thickness of the dielectric film 5 on the electrode finger disposed in the second sub-region 3b2. The first sub-region 3b1, the second sub-region 3b2, and the third sub-region 3b3 are obtained by equally dividing, in the x-axis direction, the electrode finger region 3b in which the plurality of electrode fingers 411a, 411b, and 421 are disposed on the substrate 3. The second sub-region 3b2 is located between the first sub-region 3b1 and the third sub-region 3b3.

With this configuration, mass can be added, by the dielectric film 5 with a larger thickness, to the electrode fingers 411a, 411b, and 421 disposed in the first sub-region 3b1 and the third sub-region 3b3. Accordingly, the reflectivity can be increased, and the advantageous effect of confining a surface acoustic wave in the surface acoustic wave resonator 1 can be improved. As a result, as depicted in FIG. 6, the Q factor of the surface acoustic wave resonator 1 can be improved. Further, because mass can be added by a dielectric, it becomes easier to ensure a distance between adjacent electrode fingers than in a case where mass is added by a conductor, and a decrease in electric power handling capability can be reduced or prevented.

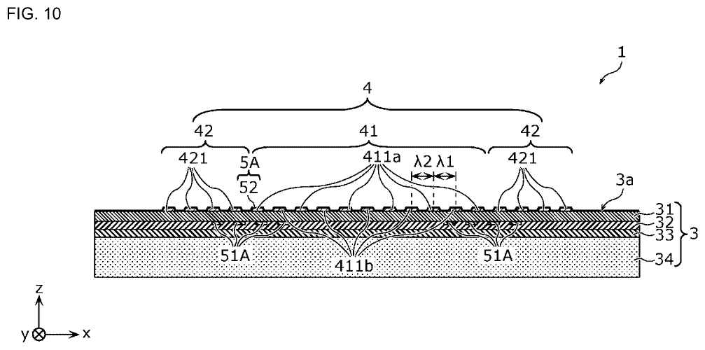

Next, modification 1 of example embodiment 1 of the present invention is described. The present modification is different from example embodiment 1 mainly in that a plurality of load layers 51A are disposed in the substrate 3 instead of the plurality of load layers 51. With reference to FIG. 10, the present modification is described below with a focus on differences from example embodiment 1.

FIG. 10 is a cross-sectional view of the surface acoustic wave resonator 1 according to the present modification. FIG. 10 is a diagram for explaining a typical configuration of the surface acoustic wave resonator 1, and the configuration of the surface acoustic wave resonator 1 is not limited to the configuration depicted in FIG. 10. Accordingly, a description of the surface acoustic wave resonator 1 provided below should not be construed in a limited manner.

The surface acoustic wave resonator 1 includes the substrate 3, the plurality of electrodes 4, a dielectric film 5A, and the load layers 51A.

The dielectric film 5A is disposed on the substrate 3, and covers the substrate 3 and the plurality of electrodes 4. The dielectric film 5A includes the protective film 52, and does not include a plurality of load layers. In the present modification, the surface acoustic wave resonator 1 is not required to include the dielectric film 5A.

The plurality of load layers 51A are an example of the plurality of first load layers, and include a dielectric. In the present modification, the plurality of load layers 51A are spaced apart from each other in the substrate. Each of the load layers 51A at least partially overlaps at least one corresponding electrode finger in plan view of the substrate 3. Thus, the load layers 51A can add mass to some of the electrode fingers 411a, 411b, and 421.

As a material of the load layers 51A, a material having a density higher than that of the low acoustic velocity layer 32 is used. Specifically, for example, it is possible to use tantalum pentoxide (Ta₂O₅), silicon dioxide, silicon nitride, alumina, or any combination of these materials. The material of the load layers 51A is not limited to these materials.

The load layers 51A may be disposed in a layer different from the low acoustic velocity layer 32 in the substrate 3. For example, the load layers 51A may be disposed in the piezoelectric layer 31, the high acoustic velocity layer 33, or the support substrate 34.

As described above, in the surface acoustic wave resonator 1 according to the present modification, the plurality of load layers 51A may be disposed in the substrate 3.

With this configuration, the load layers 51A are not in contact with the electrode fingers 411a, 411b, and 421, and thus the Q factor can be improved while fluctuations in characteristics of the surface acoustic wave resonator 1 are reduced or prevented.

Further, for example, in the surface acoustic wave resonator 1 according to the present modification, the substrate 3 may further include the low acoustic velocity layer 32 in which the acoustic velocity of a propagating bulk wave is lower than the acoustic velocity of an acoustic wave propagating in the piezoelectric layer 31. In addition, the piezoelectric layer 31 may be disposed on the low acoustic velocity layer 32, and the plurality of load layers 51A may be disposed in the low acoustic velocity layer 32.

With this configuration, the load layers 51A can be disposed in the low acoustic velocity layer 32, and the Q factor can be improved even in such a case.

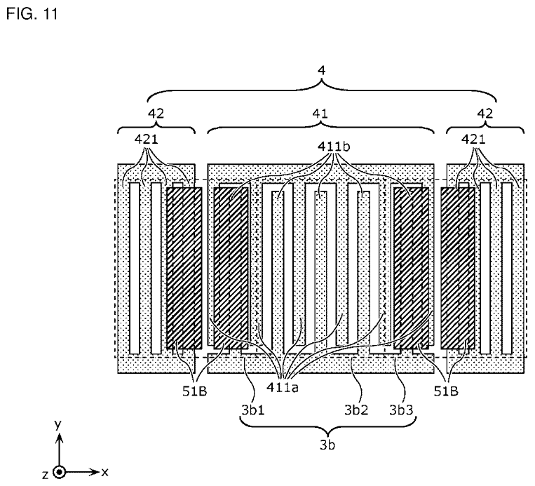

Next, modification 2 of example embodiment 1 of the present invention is described. The present modification is different from example embodiment 1 mainly in that one load layer 51 overlaps a plurality of electrode fingers. With reference to FIG. 11, the present modification is described below with a focus on differences from example embodiment 1.

FIG. 11 is a plan view of the plurality of electrodes 4 and a plurality of load layers 51B according to the present modification. Specifically, FIG. 11 is a diagram obtained by orthogonally projecting the electrodes 4 and the load layers 51B onto an xy-plane.

FIG. 11 is a diagram for explaining a typical positional relationship between the plurality of electrodes 4 and the plurality of load layers 51B, and the positional relationship between the plurality of electrodes 4 and the plurality of load layers 51B is not limited to the positional relationship depicted in FIG. 11. Accordingly, a description of the plurality of electrodes 4 and the plurality of load layers 51B provided below should not be construed in a limited manner.

The plurality of load layers 51B are an example of the plurality of first load layers, and include a dielectric. Also in the present modification, the plurality of load layers 51B include a plurality of load films (example of the plurality of first load films) spaced apart from each other on the substrate 3, similarly to the plurality of load layers 51 in example embodiment 1. Each of the load layers 51B at least partially overlaps at least two corresponding electrode fingers in plan view of the substrate 3. Thus, the load layers 51B can add mass to some of the electrode fingers 411a, 411b, and 421. As a material of the load layers 51B, a material the same as or similar to that of the load layers 51 in example embodiment 1 can be used.

In the present modification, each of the plurality of load layers 51B at least partially overlaps corresponding two electrode fingers 411a and 411b or 421 in plan view of the substrate 3. In FIG. 11, each of the two load layers 51B at least partially overlaps two corresponding electrode fingers 411a and 411b in plan view of the substrate 3. Further, each of the other two load layers 51B at least partially overlaps corresponding two electrode fingers 421.

As described above, in the surface acoustic wave resonator 1 according to the present modification, each of the plurality of load layers 51B may at least partially overlap a corresponding plurality of electrode fingers in plan view of the substrate 3.

Even in this case, the Q factor of the surface acoustic wave resonator 1 can be improved similarly to example embodiment 1.

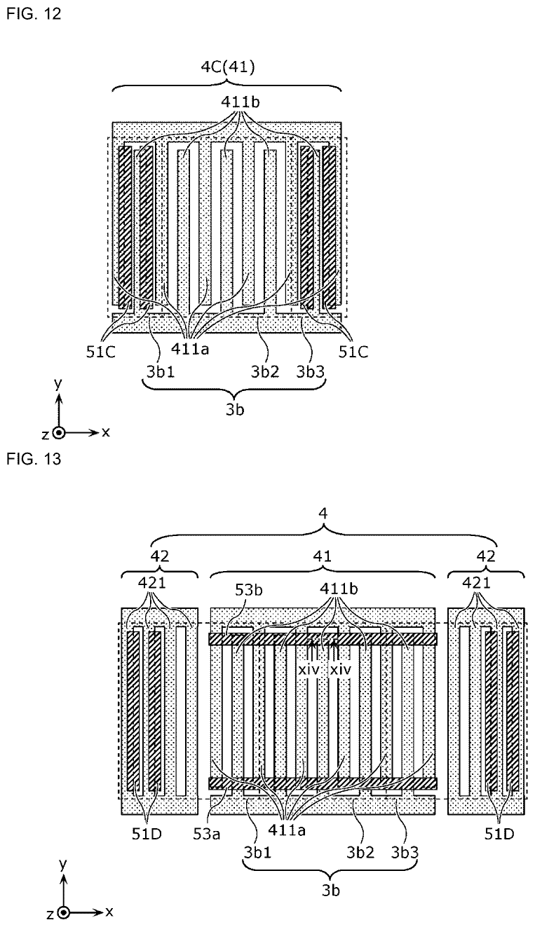

Next, modification 3 of example embodiment 1 of the present invention is described. The present modification is different from example embodiment 1 mainly in that the pair of reflector electrodes are not included in the surface acoustic wave resonator. With reference to FIG. 12, the present modification is described below with a focus on differences from example embodiment 1.

FIG. 12 is a plan view of an electrode 4C and a plurality of load layers 51C according to the present modification. Specifically, FIG. 12 is a diagram obtained by orthogonally projecting the electrode 4C and the load layers 51C onto an xy-plane.

FIG. 12 is a diagram for explaining a typical positional relationship between the electrode 4C and the plurality of load layers 51C, and the positional relationship between the electrode 4C and the plurality of load layers 51C is not limited to the positional relationship depicted in FIG. 12. Accordingly, a description of the electrode 4C and the plurality of load layers 51C provided below should not be construed in a limited manner.

The electrode 4C includes the IDT electrode 41, and is disposed on the substrate 3. In the present modification, the electrode 4C does not include the pair of reflector electrodes 42.

The plurality of load layers 51C are an example of the plurality of first load layers, and include a dielectric. Also in the present modification, the plurality of load layers 51C include a plurality of load films (example of the plurality of first load films) spaced apart from each other on the substrate 3, similarly to the plurality of load layers 51 in example embodiment 1. Each of the load layers 51C at least partially overlaps at least one corresponding electrode finger in plan view of the substrate 3. Thus, the load layers 51C can add mass to some of the electrode fingers 411a and 411b. As a material of the load layers 51C, a material the same as or similar to that of the load layers 51 in example embodiment 1 can be used.

As described above, in the surface acoustic wave resonator 1 according to the present modification, the electrode 4C is not required to include the reflector electrodes 42.

Even in such a case, the surface acoustic wave resonator 1 can improve the Q factor similarly to example embodiment 1.

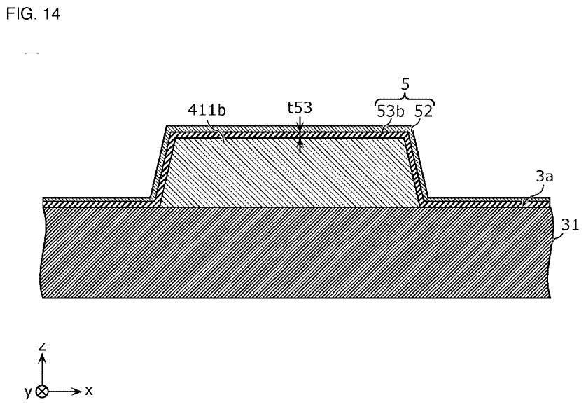

Next, modification 4 of example embodiment 1 of the present invention is described. The present modification is different from example embodiment 1 mainly in that tip portions of the electrode fingers 411a and 411b of the IDT electrode 41 overlap other load layers. With reference to FIGS. 13 and 14, the present modification is described below with a focus on differences from example embodiment 1.

FIG. 13 is a plan view of the plurality of electrodes 4 and a plurality of load layers 51D, 53a, and 53b according to the present modification. Specifically, FIG. 13 is a diagram obtained by orthogonally projecting the electrodes 4 and the load layers 51D, 53a, and 53b onto an xy-plane.

FIG. 14 is a partial cross-sectional view of the surface acoustic wave resonator 1 according to the present modification. Specifically, FIG. 14 depicts a cross section taken along line xiv-xiv in FIG. 13.

FIGS. 13 and 14 are diagrams for explaining a typical positional relationship between the plurality of electrodes 4 and the plurality of load layers 51D, 53a, and 53b, and the positional relationship between the plurality of electrodes 4 and the plurality of load layers 51D, 53a, and 53b is not limited to the positional relationship depicted in FIGS. 13 and 14. Accordingly, a description of the plurality of electrodes 4 and the plurality of load layers 51D, 53a, and 53b provided below should not be construed in a limited manner.

The plurality of load layers 51D are an example of the plurality of first load layers, and include a dielectric. Also in the present modification, the plurality of load layers 51D include a plurality of load films (example of the plurality of first load films) spaced apart from each other on the substrate 3, similarly to the plurality of load layers 51 in example embodiment 1. Each of the load layers 51D at least partially overlaps at least one corresponding electrode finger in plan view of the substrate 3. Thus, the load layers 51D can add mass to some of the electrode fingers 421. As a material of the load layers 51D, a material the same as or similar to that of the load layers 51 in example embodiment 1 can be used.

The plurality of load layers 53a and 53b are an example of a plurality of second load layers, and include, for example, a dielectric or a conductor. The plurality of load layers 53a and 53b include a plurality of load films (example of a plurality of second load films) disposed on the substrate 3. The load layer 53a at least partially overlaps the tip portions of the plurality of electrode fingers 411a in plan view of the substrate 3. The load layer 53b at least partially overlaps the tip portions of the plurality of electrode fingers 411b in plan view of the substrate 3. Thus, the load layers 53a and 53b can add mass to the tip portions of the electrode fingers 411a and 411b of the IDT electrode 41. As a material of the load layers 53a and 53b, the same material as the load layers 51D can be used. The material of the load layers 53a and 53b may be different from the material of the load layers 51D.

As depicted in FIG. 14, a thickness t53 of the load layer 53b on the electrode fingers 411b is smaller than a thickness of the load layers 51D on the electrode fingers 421. Similarly, a thickness of the load layer 53a on the electrode fingers 411a is smaller than the thickness t51a of the load layers 51D on the electrode fingers 421. That is, the thickness of the load layers 51D is larger than that of the load layers 53a and 53b. Here, the thickness of the load layer is obtained by an average of the thickness of the load layer on the top surfaces of the plurality of electrode fingers.

The thickness of the load layers 51D may be the same as that of the load layers 53a and 53b. The expression “thicknesses of two objects are the same” does not mean only that the thicknesses are exactly the same, but means that an error within such a range that the thicknesses are regarded as substantially the same (for example, about ±10%) is allowed.

As described above, the surface acoustic wave resonator 1 according to the present modification may further include the plurality of load layers 53a and 53b that at least partially overlap the tip portions of the electrode fingers 411a and 411b of the IDT electrode 41 among the plurality of electrode fingers 411a, 411b, and 421 in plan view of the substrate 3.

With this configuration, as an additional advantage, a transverse mode can be constrained by a piston mode, and a ripple attributed to the transverse mode can be reduced or prevented.

Further, for example, in the surface acoustic wave resonator 1 according to the present modification, the plurality of load layers 51D may include a plurality of first load films disposed on the substrate 3, and the plurality of load layers 53a and 53b may include a plurality of second load films that are composed of the same material as the plurality of load layers 51D and are disposed on the substrate 3.

With this configuration, the load layers 51D and the load layers 53a and 53b can be provided with the same material, and a manufacturing step for the surface acoustic wave resonator 1 can be simplified.

Further, for example, in the surface acoustic wave resonator 1 according to the present modification, the thickness of the plurality of load layers 51D may be the same as the thickness of the plurality of load layers 53a and 53b.

With this configuration, the load layers 51D and the load layers 53a and 53b can be provided in a single step, and the manufacturing step for the surface acoustic wave resonator 1 can be further simplified.

Further, for example, in the surface acoustic wave resonator 1 according to the present modification, the thickness of the plurality of load layers 51D may be larger than the thickness of the plurality of load layers 53a and 53b.

With this configuration, for the load layers 51D for improving the Q factor and the load layers 53a and 53b for constraining the transverse mode, film thicknesses suitable for purposes thereof can be used. In particular, the Q factor can be further improved by making the load layers 51D for improving the Q factor thicker than the load layers 53a and 53b for constraining the transverse mode.

Next, modification 5 of example embodiment 1 of the present invention is described. The present modification is different from example embodiment 1 mainly in that the IDT electrodes and the reflector electrodes are disposed on both surfaces of the piezoelectric layer 31. With reference to FIGS. 1, 15, and 16, the present modification is described below with a focus on differences from example embodiment 1.

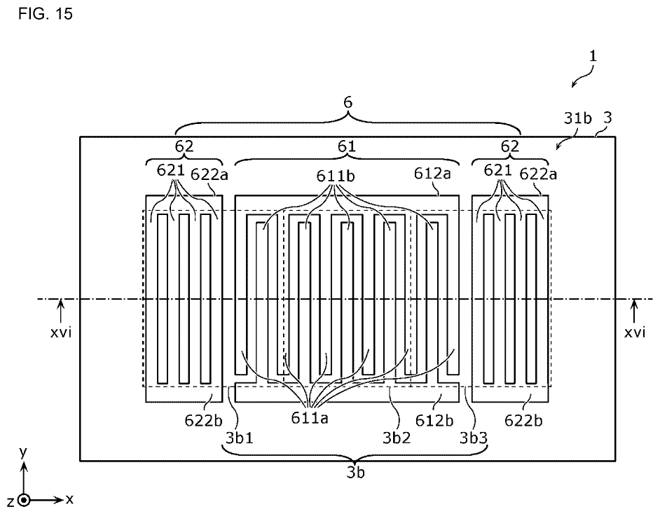

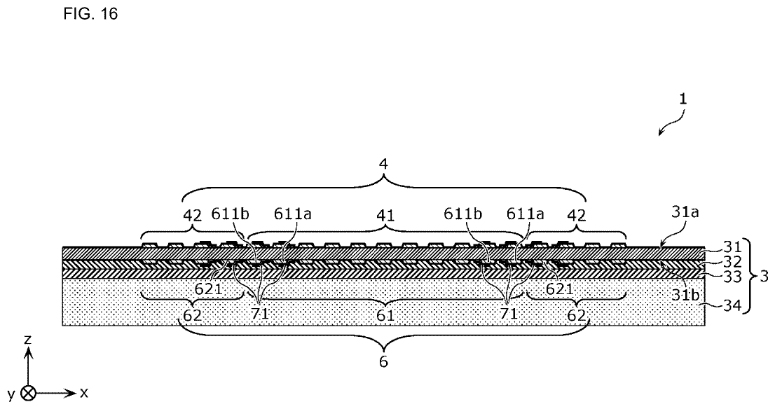

FIG. 15 is a plan view of the surface acoustic wave resonator 1 according to the present modification, and is a diagram obtained when the main surface 31b side of the piezoelectric layer 31 is viewed from the z-axis positive side in a see-through manner. FIG. 16 is a cross-sectional view of the surface acoustic wave resonator 1 according to the present modification. The cross section of the surface acoustic wave resonator 1 in FIG. 16 is a cross section taken along line xvi-xvi in FIG. 15.

The piezoelectric layer 31 includes the main surfaces 31a and 31b opposed to each other. The main surface 31a is an example of a first main surface, and the main surface 31b is an example of a second main surface. The plurality of electrodes 4 are disposed on the main surface 31a as depicted in FIG. 1, and a plurality of electrodes 6 are disposed on the main surface 31b as depicted in FIG. 15.

The plurality of electrodes 6 are an example of at least one second electrode, and include an IDT electrode 61 and a pair of reflector electrodes 62.

The IDT electrode 61 is an example of a second IDT electrode. The IDT electrode 61 includes two interdigitated comb-shaped electrodes disposed on the piezoelectric layer 31, and can convert an electrical signal to a surface acoustic wave and inversely convert a surface acoustic wave to an electrical signal. The IDT electrode 61 includes a plurality of electrode fingers 611a and 611b and busbar electrodes 612a and 612b.

The plurality of electrode fingers 611a and 611b are an example of a plurality of second electrode fingers. The electrode fingers 611a and 611b are alternately arranged along the x-axis (first axis), and each extend along the y-axis (second axis). One end of each of the electrode fingers 611a is connected to the busbar electrode 612a, and the electrode fingers 611a extend from the busbar electrode 612a in the negative direction of the y-axis. One end of each of the electrode fingers 611b is connected to the busbar electrode 612b, and the electrode fingers 611b extend from the busbar electrode 612b in the positive direction of the y-axis. The electrode fingers 611a and 611b are not required to be disposed alternately one by one. For example, sets of two or more electrode fingers 611a and sets of two or more electrode fingers 611b may be alternately disposed.

In plan view of the substrate 3, the plurality of electrode fingers 611a and 611b overlap the plurality of electrode fingers 411a and 411b in a one-to-one relationship. The electrode fingers 411a and the electrode fingers 611a are excited in phase, and the electrode fingers 411b and the electrode fingers 611b are excited in phase. This makes it possible to reduce or prevent a spurious signal in a higher-order mode or the like. In plan view of the substrate 3, the electrode fingers 611a and 611b are not required to completely overlap the electrode fingers 411a and 411b. For example, a portion of the electrode fingers 611a and 611b is not required to overlap the electrode fingers 411a and 411b, and a portion of the electrode fingers 411a and 411b is not required to overlap the electrode fingers 611a and 611b.

The busbar electrode 612a extends along the x-axis, and is connected to the one end of each of the electrode fingers 611a. The busbar electrode 612a is disposed in parallel with the busbar electrode 612b, and is spaced apart from the busbar electrode 612b in the positive direction of the y-axis.

The busbar electrode 612b extends along the x-axis, and is connected to the one end of each of the electrode fingers 611b. The busbar electrode 612b is disposed in parallel with the busbar electrode 612a, and is spaced apart from the busbar electrode 612a in the negative direction of the y-axis.

The pair of reflector electrodes 62 are an example of a pair of second reflector electrodes, and are disposed on both sides of the IDT electrode 61 in the x-axis direction in order to confine a predetermined high frequency signal resonating in the IDT electrode 61 within the IDT electrode 61. That is, the IDT electrode 61 is disposed between the pair of reflector electrodes 62 in the x-axis direction. Each of the pair of reflector electrodes 62 includes a plurality of electrode fingers 621 and busbar electrodes 622a and 622b.

The plurality of electrode fingers 621 are an example of the plurality of second electrode fingers. The electrode fingers 621 are arranged along the x-axis, and each extend along the y-axis. Both ends of the electrode fingers 621 are connected to the busbar electrodes 622a and 622b. The busbar electrode 622a extends along the x-axis, and is connected to one end of each of the electrode fingers 621. The busbar electrode 622b extends along the x-axis. The busbar electrode 622b is disposed in parallel with and opposite the busbar electrode 622a, and is connected to the other end of each of the electrode fingers 621.

As materials of the IDT electrode 61 and the pair of reflector electrodes 62, for example, aluminum, titanium, gold, silver, copper, platinum, tungsten, molybdenum, ruthenium, or any combination of these materials can be used. The materials of the IDT electrode 61 and the pair of reflector electrodes 62 are not limited to these materials. Further, the materials of the IDT electrode 61 and the pair of reflector electrodes 62 may be different from each other, or may be the same.

A plurality of load layers 71 are an example of a plurality of third load layers, and include a dielectric. In the present example embodiment, the plurality of load layers 71 include a plurality of load films (example of the plurality of first load films) spaced apart from each other on the substrate 3. Each of the load layers 71 at least partially overlaps at least one corresponding electrode finger in plan view of the substrate 3. Thus, the load layers 71 can add mass to some of the electrode fingers 611a, 611b, and 621.

As a material of the load layers 71, a dielectric material is used. Specifically, for example, it is possible to use tantalum pentoxide (Ta₂O₅), niobium pentoxide (Nb₂O₅), tungsten oxide (VI) (WO₃), silicon nitride (SiN), titanium oxide (IV) (TiO₂), cerium oxide (IV) (CeO₂), hafnium oxide (IV) (HfO₂), ytterbium oxide (III) (Yb₂O₃), silicon dioxide, alumina, or any combination of these materials. The material of the load layers 71 is not limited to these materials. The load layers 71 can be made thinner by using a dielectric material having a density higher than that of the protective film 52 as the material of the load layers 71. The load layers 71 may include materials different from each other.

The electrode finger regions 3b on the main surfaces 31a and 31b of the piezoelectric layer 31 are regions in which the plurality of electrode fingers 411a, 411b, 421, 611a, 611b, and 621 are disposed, and are equally divided into the first sub-region 3b1, the second sub-region 3b2, and the third sub-region 3b3 in the x-axis direction. The electrode finger regions 3b are defined as rectangular regions that enclose the plurality of electrode fingers 411a, 411b, 421, 611a, 611b, and 621 with a minimum area. In FIGS. 1 and 15, the first sub-region 3b1, the second sub-region 3b2, and the third sub-region 3b3 include a left partial region, a central partial region, and a right partial region, respectively, of the electrode finger region 3b. The second sub-region 3b2 is located between the first sub-region 3b1 and the third sub-region 3b3.

A cross-sectional configuration and arrangement of the plurality of electrode fingers 611a, 611b, and 621 and the plurality of load layers 71 are the same as or similar to those in example embodiment 1, and thus depiction and description thereof are omitted.

The configuration of the surface acoustic wave resonator 1 is not limited to the configuration depicted in FIGS. 1, 15, and 16. For example, the surface acoustic wave resonator 1 may include only the load layers 51 or only the load layers 71. That is, the load layers may be overlapped with only the electrodes 4 disposed on the main surface 31a or only the electrodes 6 disposed on the main surface 31b.

As described above, in the surface acoustic wave resonator 1 according to the present modification, the piezoelectric layer 31 may include the main surfaces 31a and 31b opposed to each other, and at least one electrode 4 may be disposed on one of the main surfaces 31a and 31b. In addition, the surface acoustic wave resonator 1 may further include at least one electrode 6 that is disposed on the other of the main surfaces 31a and 31b and includes the IDT electrode 61. In addition, at least one electrode 6 may include the plurality of electrode fingers 611a, 611b, and 621 that are arranged along the x-axis on the substrate 3 and each extend along the y-axis perpendicular to the x-axis, and the plurality of electrode fingers 611a, 611b, and 621 may overlap the plurality of electrode fingers 411a, 411b, and 421 in a one-to-one relationship in plan view of the substrate 3.

With this configuration, the electrode fingers 611a and the electrode fingers 411a are excited in phase, and the electrode fingers 611b and the electrode fingers 411b are excited in phase. This can reduce or prevent a spurious signal in a higher-order mode or the like.

Further, for example, the surface acoustic wave resonator 1 according to the present modification may further include the plurality of load layers 71 that are spaced apart from each other on the substrate 3 or in the substrate 3 and include a dielectric, and each of the plurality of load layers 71 may at least partially overlap at least one corresponding electrode finger in plan view of the substrate 3. In addition, the number of electrode fingers overlapping the plurality of load layers 71 among the electrode fingers disposed in the first sub-region 3b1 and the number of electrode fingers overlapping the plurality of load layers 71 among the electrode fingers disposed in the third sub-region 3b3 may each be larger than the number of electrode fingers overlapping the plurality of load layers 71 among the electrode fingers disposed in the second sub-region 3b2. In addition, the plurality of load layers 71 may include two or more load layers 71 overlapping the electrode fingers disposed in the first sub-region 3b1 and two or more load layers 71 overlapping the electrode fingers disposed in the third sub-region 3b3.

With this configuration, reflectivity can be increased by adding, by the load layers 71, mass to the electrode fingers 611a, 611b, and 621 disposed in the first sub-region 3b1 and the third sub-region 3b3, and the advantageous effect of confining a surface acoustic wave in the surface acoustic wave resonator 1 can be improved. As a result, the Q factor of the surface acoustic wave resonator 1 can be improved. Further, because the load layers 71 include the dielectric, it becomes easier to ensure a distance between adjacent electrode fingers than in a case where the load layers 71 include a conductor, and a decrease in electric power handling capability can be reduced or prevented.

Further, for example, in the surface acoustic wave resonator 1 according to the present modification, at least one electrode 6 may further include the pair of reflector electrodes 62, and the IDT electrode 61 may be disposed between the pair of reflector electrodes 62.

With this configuration, the advantageous effect of confining a surface acoustic wave in the surface acoustic wave resonator 1 can be further improved by the pair of reflector electrodes 62, and the Q factor of the surface acoustic wave resonator 1 can be further improved.

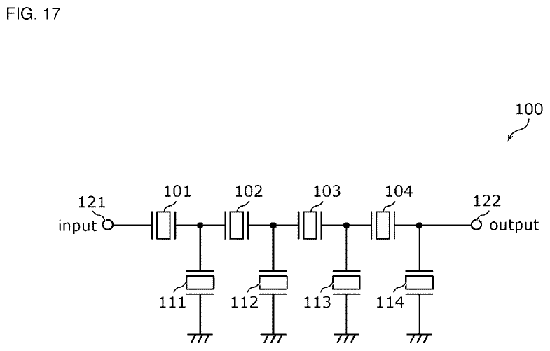

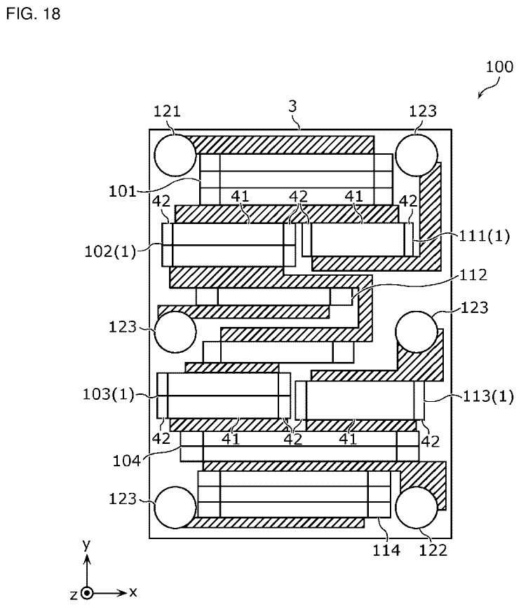

Next, example embodiment 2 of the present invention is described. In the present example embodiment, a surface acoustic wave filter including the surface acoustic wave resonator 1 according to example embodiment 1 or a modification thereof is described with reference to FIGS. 17 and 18.

FIG. 17 is a circuit configuration diagram of a surface acoustic wave filter 100 according to the present example embodiment. FIG. 17 is a diagram for explaining a typical circuit configuration of the surface acoustic wave filter 100, and the circuit configuration of the surface acoustic wave filter 100 is not limited to the circuit configuration depicted in FIG. 17. Accordingly, a description of the surface acoustic wave filter 100 provided below should not be construed in a limited manner.

The surface acoustic wave filter 100 is a ladder surface acoustic wave filter, and includes a plurality of series-arm resonators 101 to 104 and a plurality of parallel-arm resonators 111 to 114.

The series-arm resonators 101 to 104 are connected in series between an input terminal 121 and an output terminal 122. Specifically, one end of the series-arm resonator 101 is connected to the input terminal 121, and the other end of the series-arm resonator 101 is connected to one end of the series-arm resonator 102. The other end of the series-arm resonator 102 is connected to one end of the series-arm resonator 103. The other end of the series-arm resonator 103 is connected to one end of the series-arm resonator 104. The other end of the series-arm resonator 104 is connected to the output terminal 122.

The parallel-arm resonators 111 to 114 are connected in parallel between a path connecting the input terminal 121 and the output terminal 122 and ground. Specifically, the parallel-arm resonator 111 is connected between a path connecting the series-arm resonators 101 and 102 and the ground. The parallel-arm resonator 112 is connected between a path connecting the series-arm resonators 102 and 103 and the ground. The parallel-arm resonator 113 is connected between a path connecting the series-arm resonators 103 and 104 and the ground. The parallel-arm resonator 114 is connected between a path connecting the series-arm resonator 104 and the output terminal 122 and the ground.

In the present example embodiment, at least one of the series-arm resonators 101 to 104 and the parallel-arm resonators 111 to 114 is the surface acoustic wave resonator 1 according to example embodiment 1 or a modification thereof.

For example, of the series-arm resonators 101 to 104 and the parallel-arm resonators 111 to 114, only the parallel-arm resonators 111 to 114 may include the surface acoustic wave resonator 1. That is, for example, the surface acoustic wave resonator 1 may be included in the parallel-arm resonators 111 to 114, and the surface acoustic wave resonator 1 may not be included in the series-arm resonators 101 to 104.

Further, when the surface acoustic wave resonator 1 is included in the series-arm resonators 101 to 104 and the surface acoustic wave resonator 1 is included in the parallel-arm resonators 111 to 114, the number, shape, size, or any combination thereof regarding the plurality of load layers 51, 51A, 51B, 51C, or 51D may be different between the surface acoustic wave resonator 1 included in the series-arm resonators 101 to 104 and the surface acoustic wave resonator 1 included in the parallel-arm resonators 111 to 114.

For example, the area of a portion where the plurality of load layers 51, 51A, 51B, 51C, or 51D overlap the plurality of electrode fingers in the surface acoustic wave resonator 1 included in the series-arm resonators 101 to 104 may be smaller than the area of a portion where the plurality of load layers 51, 51A, 51B, 51C, or 51D overlap the plurality of electrode fingers in the surface acoustic wave resonator 1 included in the parallel-arm resonators 111 to 114.

Further, for example, the number of electrode fingers overlapping the plurality of load layers 51, 51A, 51B, 51C, or 51D in the surface acoustic wave resonator 1 included in the series-arm resonators 101 to 104 may be smaller than the number of electrode fingers overlapping the plurality of load layers 51, 51A, 51B, 51C, or 51D in the surface acoustic wave resonator 1 included in the parallel-arm resonators 111 to 114.

Further, for example, the thickness of the plurality of load layers 51, 51A, 51B, 51C, or 51D in the surface acoustic wave resonator 1 included in the series-arm resonators 101 to 104 may be smaller than the thickness of the plurality of load layers 51, 51A, 51B, 51C, or 51D in the surface acoustic wave resonator 1 included in the parallel-arm resonators 111 to 114.

Further, when each of two or more series-arm resonators is the surface acoustic wave resonator 1, for example, the number, shape, size, or any combination thereof regarding the plurality of load layers 51, 51A, 51B, 51C, or 51D may be different depending on a distance from the input terminal 121.

For example, when each of two or more series-arm resonators is the surface acoustic wave resonator 1, the number of electrode fingers overlapping the plurality of load layers 51, 51A, 51B, 51C, or 51D in the series-arm resonator closer to the input terminal 121 (first series-arm resonator) may be smaller than the number of electrode fingers overlapping the plurality of load layers 51, 51A, 51B, 51C, or 51D in the series-arm resonator farther from the input terminal 121 (second series-arm resonator).

A relative distance of two series-arm resonators with respect to the input terminal 121 is specified by the circuit configuration of the surface acoustic wave filter 100. Specifically, the series-arm resonator farther from the input terminal 121 (for example, series-arm resonator 104) is connected to the input terminal 121 through the series-arm resonator closer to the input terminal 121 (for example, series-arm resonator 101). Conversely, the series-arm resonator closer to the input terminal 121 (for example, series-arm resonator 101) is connected to the input terminal 121 without interposition of the series-arm resonator farther from the input terminal 121 (for example, series-arm resonator 104).

Similarly, when each of two or more parallel-arm resonators is the surface acoustic wave resonator 1, for example, the number, shape, size, or any combination thereof regarding the plurality of load layers 51, 51A, 51B, 51C, or 51D may be different depending on a distance from the input terminal 121.

For example, when each of two or more parallel-arm resonators is the surface acoustic wave resonator 1, the number of electrode fingers overlapping the plurality of load layers 51, 51A, 51B, 51C, or 51D in the parallel-arm resonator closer to the input terminal 121 (first parallel-arm resonator) may be smaller than the number of electrode fingers overlapping the plurality of load layers 51, 51A, 51B, 51C, or 51D in the parallel-arm resonator farther from the input terminal 121 (second parallel-arm resonator).

A relative distance of two parallel-arm resonators with respect to the input terminal 121 is specified by the circuit configuration of the surface acoustic wave filter 100. Specifically, a node on the path connecting the input terminal 121 and the output terminal 122 (hereinafter, referred to as series path), connected to the parallel-arm resonator farther from the input terminal 121 (for example, parallel-arm resonator 114), is connected to the input terminal 121 through a node on the series path to which the parallel-arm resonator closer to the input terminal 121 (for example, parallel-arm resonator 111) is connected. Conversely, a node on the series path to which the parallel-arm resonator closer to the input terminal 121 (for example, parallel-arm resonator 111) is connected is connected to the input terminal 121 without interposition of a node on the series path to which the parallel-arm resonator farther from the input terminal 121 (for example, parallel-arm resonator 114) is connected.

The surface acoustic wave filter using the surface acoustic wave resonator 1 according to example embodiment 1 or a modification thereof is not limited to a ladder surface acoustic wave filter 100. For example, the surface acoustic wave filter may include a longitudinally coupled surface acoustic wave resonator.

Next, example of the surface acoustic wave filter 100 configured as described above is described with reference to FIG. 18. FIG. 18 is a plan view of the surface acoustic wave filter 100 according to the present example embodiment. In FIG. 18, hatching represents wiring lines.

FIG. 18 depicts one example of the surface acoustic wave filter 100, and the surface acoustic wave filter 100 can be provided using any of a wide variety of circuit configurations and circuit techniques. Accordingly, a description of the surface acoustic wave filter 100 provided below should not be construed in a limited manner.

In FIG. 18, the input terminal 121 is disposed at an upper left corner of the substrate 3, and the output terminal 122 is disposed at a lower right corner of the substrate 3. A plurality of ground terminals 123 are discretely disposed on the substrate 3. The series-arm resonators 101 to 104 are arranged in order in the negative direction of the y-axis, and the parallel-arm resonators 111 to 114 are arranged in order in the negative direction of the y-axis.

The series-arm resonators 101 to 104 and/or the parallel-arm resonators 111 to 114 that include the surface acoustic wave resonator 1 according to example embodiment 1 or a modification thereof may be determined in accordance with the arrangement on the substrate 3 regarding the series-arm resonators 101 to 104 and the parallel-arm resonators 111 to 114 disposed in this manner.

For example, the surface acoustic wave resonator 1 according to example embodiment 1 or a modification thereof may be used as each of a plurality of resonators arranged along the x-axis. In this case, in FIG. 18, the surface acoustic wave resonator 1 is used as each of the series-arm resonator 102 and the parallel-arm resonator 111, and the surface acoustic wave resonator 1 is used as each of the series-arm resonator 103 and the parallel-arm resonator 113.

As described above, the surface acoustic wave filter 100 according to the present example embodiment includes at least one series-arm resonator 101 to 104 and at least one parallel-arm resonator 111 to 114, and at least one of at least one series-arm resonator 101 to 104 and at least one parallel-arm resonator 111 to 114 is the surface acoustic wave resonator 1 described in example embodiment 1 or a modification thereof.

With this configuration, the surface acoustic wave resonator 1 described in example embodiment 1 or a modification thereof can be used for the ladder surface acoustic wave filter 100, and improvement in characteristics of the surface acoustic wave filter 100 (for example, reduction in loss and reduction in a ripple) can be achieved.

Further, for example, in the surface acoustic wave filter 100 according to the present example embodiment, at least one parallel-arm resonator 111 to 114 may include the surface acoustic wave resonator 1, and at least one series-arm resonator 101 to 104 may not include the surface acoustic wave resonator 1.

With this configuration, because the surface acoustic wave resonator 1 is used as at least one parallel-arm resonator 111 to 114, the Q factor of at least one parallel-arm resonator 111 to 114 can be improved, and the characteristics of the surface acoustic wave filter 100 can be improved. Further, because the surface acoustic wave resonator 1 is not used as at least one series-arm resonator 101 to 104, a decrease in electric power handling capability and an increase in a ripple in the longitudinal mode due to the plurality of load layers 51, 51A, 51B, 51C, or 51D can be reduced or prevented. In particular, because power durability of the series-arm resonator becomes more severe than that of the parallel-arm resonator when a pass band shifts to a higher frequency side with an increase in temperature, an advantageous effect of reducing or preventing the decrease in the electric power handling capability of at least one series-arm resonator 101 to 104 is significant.

Further, for example, in the surface acoustic wave filter 100 according to the present example embodiment, at least one series-arm resonator 101 to 104 may include the surface acoustic wave resonator 1, and at least one parallel-arm resonator 111 to 114 may include the surface acoustic wave resonator 1. In addition, the area of the portion where the plurality of load layers 51, 51A, 51B, 51C, or 51D overlap the plurality of electrode fingers in plan view of the substrate 3 in the surface acoustic wave resonator 1 included in at least one series-arm resonator 101 to 104 may be smaller than the area of the portion where the plurality of load layers 51, 51A, 51B, 51C, or 51D overlap the plurality of electrode fingers in plan view of the substrate 3 in the surface acoustic wave resonator 1 included in at least one parallel-arm resonator 111 to 114.

With this configuration, the longitudinal mode in the surface acoustic wave resonator 1 included in at least one series-arm resonator 101 to 104 can be constrained, and the ripple attributed to the longitudinal mode can be reduced or prevented. Thus, a bandpass characteristic of the surface acoustic wave filter 100 can be improved.

Further, for example, in the surface acoustic wave filter 100 according to the present example embodiment, at least one series-arm resonator 101 to 104 may include the surface acoustic wave resonator 1, and at least one parallel-arm resonator 111 to 114 may include the surface acoustic wave resonator 1. In addition, the number of electrode fingers overlapping the plurality of load layers 51, 51A, 51B, 51C, or 51D in the surface acoustic wave resonator 1 included in at least one series-arm resonator 101 to 104 may be smaller than the number of electrode fingers overlapping the plurality of load layers 51, 51A, 51B, 51C, or 51D in the surface acoustic wave resonator 1 included in at least one parallel-arm resonator 111 to 114.

With this configuration, the longitudinal mode in the surface acoustic wave resonator 1 included in at least one series-arm resonator 101 to 104 can be constrained, and the ripple attributed to the longitudinal mode can be reduced or prevented. Thus, the bandpass characteristic of the surface acoustic wave filter 100 can be improved.

Further, for example, in the surface acoustic wave filter 100 according to the present example embodiment, at least one series-arm resonator 101 to 104 may include the surface acoustic wave resonator 1, and at least one parallel-arm resonator 111 to 114 may include the surface acoustic wave resonator 1. In addition, the thickness of the plurality of load layers 51, 51A, 51B, 51C, or 51D in the surface acoustic wave resonator 1 included in at least one series-arm resonator 101 to 104 may be smaller than the thickness of the plurality of load layers 51, 51A, 51B, 51C, or 51D in the surface acoustic wave resonator 1 included in at least one parallel-arm resonator 111 to 114.

With this configuration, a stop-band ripple due to the surface acoustic wave resonator 1 included in at least one parallel-arm resonator 111 to 114 can be reduced or prevented, and the bandpass characteristic of the surface acoustic wave filter 100 can be improved.

Further, for example, in the surface acoustic wave filter 100 according to the present example embodiment, at least one series-arm resonator 101 to 104 may include the first series-arm resonator 101 to 104 connected in series between the input terminal 121 and the output terminal 122 and the second series-arm resonator 101 to 104 farther from the input terminal 121 than the first series-arm resonator 101 to 104. In addition, each of the first series-arm resonator 101 to 104 and the second series-arm resonator 101 to 104 may include the surface acoustic wave resonator 1, and the number of electrode fingers overlapping the plurality of load layers 51, 51A, 51B, 51C, or 51D in the first series-arm resonator 101 to 104 may be smaller than the number of electrode fingers overlapping the plurality of load layers 51, 51A, 51B, 51C, or 51D in the second series-arm resonator 101 to 104.

With this configuration, a decrease in the electric power handling capability in the series-arm resonator closer to the input terminal 121 can be reduced or prevented, and the electric power handling capability of the surface acoustic wave filter 100 can be improved. In particular, because higher power is applied to the resonator closer to the input terminal 121, an advantageous effect of improving the electric power handling capability of the surface acoustic wave filter 100 is significant.

Further, for example, in the surface acoustic wave filter 100 according to the present example embodiment, at least one parallel-arm resonator 111 to 114 may include the plurality of parallel-arm resonators 111 to 114 connected in parallel between the path connecting the input terminal 121 and the output terminal 122 and the ground, and the plurality of parallel-arm resonators 111 to 114 may include the first parallel-arm resonator 111 to 114 and the second parallel-arm resonator 111 to 114 farther from the input terminal 121 than the first parallel-arm resonator 111 to 114. In addition, each of the first parallel-arm resonator 111 to 114 and the second parallel-arm resonator 111 to 114 may include the surface acoustic wave resonator 1, and the number of electrode fingers overlapping the plurality of load layers 51, 51A, 51B, 51C, or 51D in the first parallel-arm resonator 111 to 114 may be smaller than the number of electrode fingers overlapping the plurality of load layers 51, 51A, 51B, 51C, or 51D in the second parallel-arm resonator 111 to 114.

With this configuration, a decrease in the electric power handling capability in the parallel-arm resonator closer to the input terminal 121 can be reduced or prevented, and the electric power handling capability of the surface acoustic wave filter 100 can be improved. In particular, because higher power is applied to the resonator closer to the input terminal 121, the advantageous effect of improving the electric power handling capability of the surface acoustic wave filter 100 is significant.

Further, for example, in the surface acoustic wave filter 100 according to the present example embodiment, at least two series-arm resonators 101 to 104 and at least one parallel-arm resonator 111 to 114 may include the surface acoustic wave resonators 1, and may be arranged along the x-axis on the substrate.

With this configuration, the surface acoustic wave resonators 1 can be used as at least two resonators arranged in the propagation direction of a surface acoustic wave (x-axis direction). In the surface acoustic wave resonator 1 including the load layers 51, 51A, 51B, 51C, or 51D, the advantageous effect of confining a surface acoustic wave can be improved by the load layers 51, 51A, 51B, 51C, or 51D, and thus the number of electrode fingers 421 of the reflector electrodes 42 can be reduced. This makes it possible to reduce the size of the reflector electrodes 42 in the propagation direction and reduce the size of the surface acoustic wave resonator 1. In particular, with at least two resonators arranged in the propagation direction, the size in the propagation direction becomes large and thus an advantageous effect of reducing the size of the surface acoustic wave resonator 1 is significant.

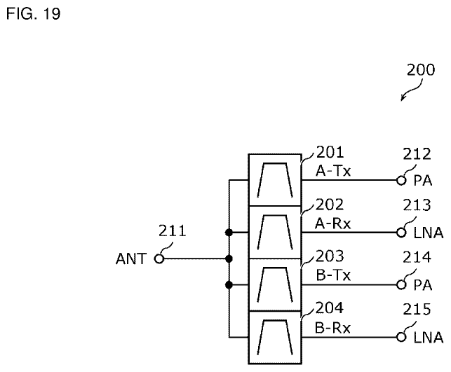

Next, example embodiment 3 of the present invention is described. In the present example embodiment, a multiplexer including the surface acoustic wave filter 100 according to example embodiment 2 is described with reference to FIG. 19.

FIG. 19 is a circuit configuration diagram of a multiplexer 200 according to the present example embodiment. FIG. 19 is a diagram for explaining a typical circuit configuration of the multiplexer 200, and the circuit configuration of the multiplexer 200 is not limited to the circuit configuration depicted in FIG. 19. Accordingly, a description of the multiplexer 200 provided below should not be construed in a limited manner.

The multiplexer 200 includes transmission filters 201 and 203 and reception filters 202 and 204.

For example, the transmission filter 201 has a pass band including a transmission band of band A, and allows a transmission signal of band A to pass through the transmission filter 201. The transmission filter 201 is connected between an antenna connection terminal 211 and a PA connection terminal 212.

For example, the reception filter 202 has a pass band including a reception band of band A, and allows a received signal of band A to pass through the reception filter 202. The reception filter 202 is connected between the antenna connection terminal 211 and an LNA connection terminal 213.

For example, the transmission filter 203 has a pass band including a transmission band of band B, and allows a transmission signal of band B to pass through the transmission filter 203. The transmission filter 203 is connected between the antenna connection terminal 211 and a PA connection terminal 214. The transmission filter 203 is not required to be included in the multiplexer 200.

For example, the reception filter 204 has a pass band including a reception band of band B, and allows a received signal of band B to pass through the reception filter 204. The reception filter 204 is connected between the antenna connection terminal 211 and an LNA connection terminal 215. The reception filter 204 is not required to be included in the multiplexer 200.

Each of bands A and B is a frequency band for a communication system using a radio access technology (RAT), and is defined in advance by a standardization organization or the like (for example, 3rd Generation Partnership Project (3GPP (registered trademark)), Institute of Electrical and Electronics Engineers (IEEE), and the like). Examples of the communication system include a 5th Generation New Radio (5G NR) system, a Long Term Evolution (LTE) system, and a wireless local area network (WLAN) system.

The antenna connection terminal 211 is an external connection terminal connected to an antenna (ANT). The antenna connection terminal 211 may be switchably connected to the antenna.

The PA connection terminal 212 is an external connection terminal connected to a power amplifier (PA). The PA connection terminal 212 may be switchably connected to the power amplifier.

The LNA connection terminal 213 is an external connection terminal connected to a low-noise amplifier (LNA). The LNA connection terminal 213 may be switchably connected to the low-noise amplifier.

The PA connection terminal 214 is an external connection terminal connected to the power amplifier (PA). The PA connection terminal 214 may be switchably connected to the power amplifier.

The LNA connection terminal 215 is an external connection terminal connected to the low-noise amplifier (LNA). The LNA connection terminal 215 may be switchably connected to the low-noise amplifier.

In the present example embodiment, at least one of the transmission filters 201 and 203 and the reception filters 202 and 204 included in the multiplexer 200 is the surface acoustic wave filter 100 according to example embodiment 2.

For example, of the transmission filters 201 and 203 and the reception filters 202 and 204, only the reception filters 202 and/or 204 may be the surface acoustic wave filter 100. That is, the reception filters 202 and/or 204 may be the surface acoustic wave filter 100 according to example embodiment 2, and the transmission filters 201 and 203 may not be the surface acoustic wave filter 100.

Further, for example, when the transmission filters 201 and/or 203 are the surface acoustic wave filter 100, the series-arm resonator 104 closest to the antenna connection terminal 211 (output terminal 122) among the series-arm resonators 101 to 104 may be the surface acoustic wave resonator 1 according to example embodiment 1. Conversely, the series-arm resonators 101 to 103 may not be the surface acoustic wave resonator 1.

Further, for example, when the transmission filters 201 and/or 203 are the surface acoustic wave filter 100, the parallel-arm resonator 114 closest to the antenna connection terminal 211 (output terminal 122) among the parallel-arm resonators 111 to 114 may be the surface acoustic wave resonator 1 according to example embodiment 1. Conversely, the parallel-arm resonators 111 to 113 may not be the surface acoustic wave resonator 1.

Further, for example, when the reception filters 202 and/or 204 are the surface acoustic wave filter 100, the series-arm resonator 101 closest to the antenna connection terminal 211 (input terminal 121) among the series-arm resonators 101 to 104 may be the surface acoustic wave resonator 1 according to example embodiment 1. Conversely, the series-arm resonators 102 to 104 may not be the surface acoustic wave resonator 1.

Further, for example, when the reception filters 202 and/or 204 are the surface acoustic wave filter 100, the parallel-arm resonator 111 closest to the antenna connection terminal 211 (input terminal 121) among the parallel-arm resonators 111 to 114 may be the surface acoustic wave resonator 1 according to example embodiment 1. Conversely, the parallel-arm resonators 112 to 114 may not be the surface acoustic wave resonator 1.

As described above, for example, the multiplexer 200 according to the present example embodiment includes the transmission filter 201 that is connected between the antenna connection terminal 211 and the PA connection terminal 212 and has a pass band including a transmission band of band A and the reception filter 202 that is connected between the antenna connection terminal 211 and the LNA connection terminal 213 and has a pass band including a reception band of band A. At least one of the transmission filter 201 or the reception filter 202 is the surface acoustic wave filter 100 described in example embodiment 2.

With this configuration, the surface acoustic wave filter 100 described in example embodiment 2 can be used for the multiplexer 200, and improvement in characteristics of the multiplexer 200 (for example, reduction in loss and reduction or prevention in a ripple) can be achieved.

Further, for example, in the multiplexer 200 according to the present example embodiment, the reception filter 202 may be the surface acoustic wave filter 100, and the transmission filter 201 may not be the surface acoustic wave filter 100.

With this configuration, because the surface acoustic wave filter 100 is used as the reception filter 202, signal loss can be reduced, and reception sensitivity can be increased. Further, because the surface acoustic wave filter 100 is not used as the transmission filter 201, a decrease in electric power handling capability due to the plurality of load layers 51, 51A, 51B, 51C, or 51D can be reduced or prevented in the transmission filter 201 required to have higher electric power handling capability.

Further, for example, in the multiplexer 200 according to the present example embodiment, the transmission filter 201 may be the surface acoustic wave filter 100 including the series-arm resonators 101 to 104 connected in series between the antenna connection terminal 211 (output terminal 122) and the PA connection terminal 212 (input terminal 121). In addition, the series-arm resonator 104 closest to the antenna connection terminal 211 among the series-arm resonators 101 to 104 may be the surface acoustic wave resonator 1 described in example embodiment 1 or a modification thereof.

With this configuration, characteristics of the transmission filter 201 can be improved because the surface acoustic wave resonator 1 described in example embodiment 1 or a modification thereof is used as the series-arm resonator 104 closest to the antenna connection terminal 211. In particular, the characteristics of the transmission filter 201 can be effectively improved by improving the Q factor of the series-arm resonator 104 closest to the antenna connection terminal 211 to which the plurality of filters (transmission filter 201 and reception filter 202) are connected.

Further, for example, in the multiplexer 200 according to the present example embodiment, the transmission filter 201 may be the surface acoustic wave filter 100 including the parallel-arm resonators 111 to 114 connected in parallel between a path connecting the antenna connection terminal 211 (output terminal 122) and the PA connection terminal 212 (input terminal 121) and ground. In addition, the parallel-arm resonator 114 closest to the antenna connection terminal 211 among the parallel-arm resonators 111 to 114 may be the surface acoustic wave resonator 1 described in example embodiment 1 or a modification thereof.

With this configuration, the characteristics of the transmission filter 201 can be improved because the surface acoustic wave resonator 1 described in example embodiment 1 or a modification thereof is used as the parallel-arm resonator 114 closest to the antenna connection terminal 211. In particular, the characteristics of the transmission filter 201 can be effectively improved by improving the Q factor of the parallel-arm resonator 114 closest to the antenna connection terminal 211 to which the plurality of filters (transmission filter 201 and reception filter 202) are connected.

Further, for example, in the multiplexer 200 according to the present example embodiment, the reception filter 202 may be the surface acoustic wave filter 100 including the series-arm resonators 101 to 104 connected in series between the antenna connection terminal 211 (input terminal 121) and the LNA connection terminal 213 (output terminal 122). In addition, the series-arm resonator 101 closest to the antenna connection terminal 211 among the series-arm resonators 101 to 104 may be the surface acoustic wave resonator 1 described in example embodiment 1 or a modification thereof.

With this configuration, characteristics of the reception filter 202 can be improved because the surface acoustic wave resonator 1 described in example embodiment 1 or a modification thereof is used as the series-arm resonator 101 closest to the antenna connection terminal 211. In particular, the characteristics of the reception filter 202 can be effectively improved by improving the Q factor of the series-arm resonator 101 closest to the antenna connection terminal 211 to which the plurality of filters (transmission filter 201 and reception filter 202) are connected.

Further, for example, in the multiplexer 200 according to the present example embodiment, the reception filter 202 may be the surface acoustic wave filter 100 including the parallel-arm resonators 111 to 114 connected in parallel between a path connecting the antenna connection terminal 211 (input terminal 121) and the LNA connection terminal 213 (output terminal 122) and ground. In addition, the parallel-arm resonator 111 closest to the antenna connection terminal 211 among the parallel-arm resonators 111 to 114 may be the surface acoustic wave resonator 1 described in example embodiment 1 or a modification thereof.

With this configuration, the characteristics of the reception filter 202 can be improved because the surface acoustic wave resonator 1 described in example embodiment 1 or a modification thereof is used as the parallel-arm resonator 111 closest to the antenna connection terminal 211. In particular, the characteristics of the reception filter 202 can be effectively improved by improving the Q factor of the parallel-arm resonator 111 closest to the antenna connection terminal 211 to which the plurality of filters (transmission filter 201 and reception filter 202) are connected.

Although the surface acoustic wave resonators, the surface acoustic wave filters, and the multiplexers according to the present invention have been described above based on the example embodiments, the surface acoustic wave resonators, the surface acoustic wave filters, and the multiplexers according to the present invention are not limited to the above-described example embodiments. The present invention also includes other example embodiments provided by combining any components in the above-described example embodiments, modifications obtained by making, for the above example embodiments, various changes conceived by those skilled in the art without departing from the scope and gist of the present invention, and various kinds of equipment incorporating the above-described high frequency circuit.

For example, in the circuit configurations of the surface acoustic wave filters and the multiplexers according to the above-described respective example embodiments, another circuit element, wiring line, or the like may be included between paths connecting the respective circuit elements and signal paths, disclosed in the drawings. For example, in the surface acoustic wave filter 100 in FIG. 17, an inductor and/or a capacitor may be connected in series and/or in parallel with any of the series-arm resonators 101 to 104 and the parallel-arm resonators 111 to 114.

Further, for example, although the surface acoustic wave resonators 1 according to the above-described respective example embodiments is a single-mode surface acoustic wave resonator, the present invention is not limited thereto. For example, the surface acoustic wave resonator 1 may be a longitudinally coupled double-mode surface acoustic wave resonator. Even in such a case, advantageous effects the same as or similar to those of the single-mode surface acoustic wave resonator can be achieved.

In the above respective example embodiments, the plurality of electrode fingers included in the IDT electrode and the reflector electrodes have a linear shape in plan view. However, the present invention is not limited thereto. For example, the plurality of electrode fingers included in the IDT electrode and/or the reflector electrodes may at least partially have a curved shape in plan view. In this case, resonant frequencies or anti-resonant frequencies may coincide or substantially coincide with each other within an intersection region of the plurality of electrode fingers. Specifically, for example, the IDT electrode and/or the reflector electrodes may include electrode fingers described in International Publication No. WO 2024/009660 or International Publication No. WO 2024/135259.

Example embodiments of the present invention can be widely used as a surface acoustic wave device for communication equipment such as a cellular phone, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A surface acoustic wave resonator comprising:
a substrate including a piezoelectric layer;
at least one first electrode on the substrate and including a first interdigital transducer (IDT) electrode; and
a plurality of first load layers spaced apart from each other on the substrate or in the substrate and including a dielectric; wherein
the at least one first electrode includes a plurality of first electrode fingers arranged along a first axis on the substrate and each extending along a second axis perpendicular or substantially perpendicular to the first axis;
each of the plurality of first load layers at least partially overlaps at least one corresponding first electrode finger of the plurality of first electrode fingers in plan view of the substrate;
a number of first electrode fingers overlapping the plurality of first load layers among the plurality of first electrode fingers in a first sub-region and a number of first electrode fingers overlapping the plurality of first load layers among the plurality of first electrode fingers in a third sub-region are each larger than a number of first electrode fingers overlapping the plurality of first load layers among the plurality of first electrode fingers in a second sub-region;
the first sub-region, the second sub-region, and the third sub-region are obtained by equally dividing, in a direction of the first axis, a region in which the plurality of first electrode fingers are located on the substrate;
the second sub-region is located between the first sub-region and the third sub-region; and
the plurality of first load layers include two or more first load layers overlapping the first electrode fingers located in the first sub-region and two or more first load layers overlapping the first electrode fingers located in the third sub-region.

2. The surface acoustic wave resonator according to claim 1, wherein
the at least one first electrode further includes a pair of first reflector electrodes; and
the first IDT electrode is located between the pair of first reflector electrodes.

3. The surface acoustic wave resonator according to claim 2, wherein
at least one of the plurality of first load layers at least partially overlaps at least one corresponding first electrode finger of the plurality of first electrode fingers of the first IDT electrode in plan view of the substrate; and
at least another one of the plurality of first load layers at least partially overlaps at least one corresponding first electrode finger of the plurality of first electrode fingers of the first reflector electrodes in plan view of the substrate.

4. The surface acoustic wave resonator according to claim 1, wherein the plurality of first load layers correspond to some of the plurality of first electrode fingers in a one-to-one relationship.

5. The surface acoustic wave resonator according to claim 4, wherein each of the plurality of first load layers overlaps a portion of a corresponding one of the first electrode fingers of the plurality of first electrode fingers in plan view of the substrate.

6. The surface acoustic wave resonator according to claim 5, wherein a midpoint of a length of each of the plurality of first load layers along the first axis is shifted along the first axis toward a center of the first IDT electrode with respect to a midpoint of a length of the corresponding one of the first electrode fingers along the first axis.

7. The surface acoustic wave resonator according to claim 1, wherein
the plurality of first load layers include a plurality of first load films located on the substrate; and
the plurality of first load films at least partially cover some of the plurality of first electrode fingers.

8. The surface acoustic wave resonator according to claim 7, wherein, in each of the plurality of first load films, a thickness of the first load film on a top surface of at least one corresponding first electrode finger of the plurality of first electrode fingers is larger than a thickness of the first load film on a side surface of the at least one corresponding first electrode finger.

9. The surface acoustic wave resonator according to claim 7, further comprising a protective film on the substrate and covering at least a portion of the substrate and the plurality of first electrode fingers.

10. The surface acoustic wave resonator according to claim 9, wherein the protective film is laminated on the plurality of first load films.

11. The surface acoustic wave resonator according to claim 9, wherein the plurality of first load films include a material different from a material of the protective film.

12. The surface acoustic wave resonator according to claim 11, wherein
the plurality of first load films include tantalum pentoxide, niobium pentoxide, tungsten oxide (VI), silicon nitride, titanium oxide (IV), cerium oxide (IV), hafnium oxide (IV), or ytterbium oxide (III); and
the material of the protective film includes silicon dioxide or silicon nitride.

13. The surface acoustic wave resonator according to claim 1, wherein the plurality of first load layers are located in the substrate.

14. The surface acoustic wave resonator according to claim 13, wherein
the substrate further includes a low acoustic velocity layer in which an acoustic velocity of a propagating bulk wave is lower than an acoustic velocity of an acoustic wave propagating in the piezoelectric layer;
the piezoelectric layer is located on the low acoustic velocity layer; and
the plurality of first load layers are located in the low acoustic velocity layer.

15. The surface acoustic wave resonator according to claim 1, wherein a spacing between a first electrode finger of the plurality of first electrode fingers overlapping the plurality of first load layers and a first electrode finger of the plurality of first electrode fingers adjacent to the first electrode finger and does not overlap the plurality of first load layers is different from a spacing between two first electrode fingers of the plurality of first electrode fingers adjacent to each other and overlapping the plurality of first load layers, or a spacing between two first electrode fingers of the plurality of first electrode fingers adjacent to each other and do not overlap the plurality of first load layers.

16. The surface acoustic wave resonator according to claim 1, wherein a duty ratio of two or more first electrode fingers of the plurality of first electrode fingers overlapping the plurality of first load layers is different from a duty ratio of two or more first electrode fingers of the plurality of first electrode fingers that do not overlap any of the plurality of first load layers.

17. The surface acoustic wave resonator according to claim 1, wherein a pitch of two or more first electrode fingers of the plurality of first electrode fingers overlapping the plurality of first load layers is different from a pitch of two or more first electrode fingers of the plurality of first electrode fingers that do not overlap any of the plurality of first load layers.

18. The surface acoustic wave resonator according to claim 1, wherein at least one width of two or more first electrode fingers of the plurality of first electrode fingers that do not overlap any of the plurality of first load layers is different from at least one other width of the two or more first electrode fingers of the plurality of first electrode fingers that do not overlap any of the plurality of first load layers.

19. The surface acoustic wave resonator according to claim 1, wherein a spacing of at least one set of first electrode fingers of the plurality of first electrode fingers adjacent to each other among two or more first electrode fingers of the plurality of first electrode fingers that do not overlap any of the plurality of first load layers is different from a spacing of at least one other set of first electrode fingers of the plurality of first electrode fingers adjacent to each other among the two or more first electrode fingers that do not overlap any of the plurality of first load layers.

20. The surface acoustic wave resonator according to claim 19, wherein spacings of a plurality of sets of first electrode fingers of the plurality of first electrode fingers adjacent to each other among two or more first electrode fingers of the plurality of first electrode fingers that do not overlap any of the plurality of first load layers are different from each other.

21. The surface acoustic wave resonator according to claim 1, further comprising a plurality of second load layers that at least partially overlap tip portions of first electrode fingers of the first IDT electrode among the plurality of first electrode fingers in plan view of the substrate.

22. The surface acoustic wave resonator according to claim 21, wherein
the plurality of first load layers include a plurality of first load films located on the substrate; and
the plurality of second load layers include a plurality of second load films including a same material as the plurality of first load films and are located on the substrate.

23. The surface acoustic wave resonator according to claim 22, wherein a thickness of the plurality of first load films is the same as a thickness of the plurality of second load films.

24. The surface acoustic wave resonator according to claim 22, wherein a thickness of the plurality of first load films is larger than a thickness of the plurality of second load films.

25. The surface acoustic wave resonator according to claim 1, wherein
the piezoelectric layer includes a first main surface and a second main surface opposed to each other;
the at least one first electrode is located on one of the first main surface and the second main surface;
the surface acoustic wave resonator further includes at least one second electrode on another one of the first main surface and the second main surface and includes a second interdigital transducer (IDT) electrode;
the at least one second electrode includes a plurality of second electrode fingers arranged along the first axis on the substrate and each extending along the second axis perpendicular or substantially perpendicular to the first axis; and
the plurality of second electrode fingers overlap the plurality of first electrode fingers in a one-to-one relationship in plan view of the substrate.

26. The surface acoustic wave resonator according to claim 25, further comprising:
a plurality of third load layers spaced apart from each other on the substrate or in the substrate and including a dielectric; wherein each of the plurality of third load layers at least partially overlaps at least one corresponding second electrode finger of the plurality of second electrode fingers in plan view of the substrate;
a number of second electrode fingers overlapping the plurality of third load layers among the plurality of second electrode fingers in the first sub-region and a number of second electrode fingers overlapping the plurality of third load layers among the plurality of second electrode fingers in the third sub-region are each larger than a number of second electrode fingers overlapping the plurality of third load layers among the plurality of second electrode fingers in the second sub-region; and
the plurality of third load layers include two or more third load layers overlapping the second electrode fingers located in the first sub-region and two or more third load layers overlapping the second electrode fingers in the third sub-region.

27. The surface acoustic wave resonator according to claim 25, wherein
the at least one second electrode further includes a pair of second reflector electrodes; and
the second IDT electrode is located between the pair of second reflector electrodes.

28. A surface acoustic wave filter comprising:
at least one series-arm resonator; and
at least one parallel-arm resonator, wherein
at least one of the at least one series-arm resonator and the at least one parallel-arm resonator includes the surface acoustic wave resonator according to claim 1.

29. The surface acoustic wave filter according to claim 28, wherein
the at least one parallel-arm resonator includes the surface acoustic wave resonator; and
the at least one series-arm resonator does not include the surface acoustic wave resonator.

30. The surface acoustic wave filter according to claim 28, wherein
the at least one series-arm resonator includes the surface acoustic wave resonator;
the at least one parallel-arm resonator includes the surface acoustic wave resonator; and
an area of a portion where the plurality of first load layers overlap the plurality of first electrode fingers in plan view of the substrate in the surface acoustic wave resonator included in the at least one series-arm resonator is smaller than an area of a portion where the plurality of first load layers overlap the plurality of first electrode fingers in plan view of the substrate in the surface acoustic wave resonator included in the at least one parallel-arm resonator.

31. The surface acoustic wave filter according to claim 28, wherein
the at least one series-arm resonator includes the surface acoustic wave resonator;
the at least one parallel-arm resonator includes the surface acoustic wave resonator; and
a number of first electrode fingers of the plurality of first electrode fingers overlapping the plurality of first load layers in the surface acoustic wave resonator included in the at least one series-arm resonator is smaller than a number of first electrode fingers of the plurality of first electrode fingers overlapping the plurality of first load layers in the surface acoustic wave resonator included in the at least one parallel-arm resonator.

32. The surface acoustic wave filter according to claim 28, wherein
the at least one series-arm resonator includes the surface acoustic wave resonator;
the at least one parallel-arm resonator includes the surface acoustic wave resonator; and
a thickness of the plurality of first load layers in the surface acoustic wave resonator included in the at least one series-arm resonator is smaller than a thickness of the plurality of first load layers in the surface acoustic wave resonator included in the at least one parallel-arm resonator.

33. The surface acoustic wave filter according to claim 28, wherein
the at least one series-arm resonator includes a first series-arm resonator connected in series between an input terminal and an output terminal and a second series-arm resonator farther from the input terminal than the first series-arm resonator;
each of the first series-arm resonator and the second series-arm resonator includes the surface acoustic wave resonator; and
a number of first electrode fingers of the plurality of first electrode fingers overlapping the plurality of first load layers in the first series-arm resonator is smaller than a number of first electrode fingers of the plurality of first electrode fingers overlapping the plurality of first load layers in the second series-arm resonator.

34. The surface acoustic wave filter according to claim 28, wherein
the at least one parallel-arm resonator includes a plurality of parallel-arm resonators connected in parallel between a path connecting an input terminal and an output terminal and ground;
the plurality of parallel-arm resonators include a first parallel-arm resonator and a second parallel-arm resonator farther from the input terminal than the first parallel-arm resonator;
each of the first parallel-arm resonator and the second parallel-arm resonator includes the surface acoustic wave resonator; and
a number of first electrode fingers of the plurality of first electrode fingers overlapping the plurality of first load layers in the first parallel-arm resonator is smaller than a number of first electrode fingers of the plurality of first electrode fingers overlapping the plurality of first load layers in the second parallel-arm resonator.

35. The surface acoustic wave filter according to claim 28, wherein at least two of the at least one series-arm resonator and the at least one parallel-arm resonator include the surface acoustic wave resonators and are arranged along the first axis on the substrate.

36. A multiplexer comprising:
a transmission filter connected between an antenna connection terminal and a power amplifier (PA) connection terminal and includes a pass band including a transmission band of a predetermined band; and
a reception filter that is connected between the antenna connection terminal and a low-noise amplifier (LNA) connection terminal and includes a pass band including a reception band of the predetermined band; wherein
at least one of the transmission filter or the reception filter includes the surface acoustic wave filter according to claim 28.

37. The multiplexer according to claim 36, wherein
the reception filter includes the surface acoustic wave filter; and
the transmission filter does not include the surface acoustic wave filter.

38. The multiplexer according to claim 36, wherein
the transmission filter includes the surface acoustic wave filter;
the at least one series-arm resonator includes a plurality of series-arm resonators connected in series between the antenna connection terminal and the PA connection terminal; and
the series-arm resonator closest to the antenna connection terminal among the plurality of series-arm resonators includes the surface acoustic wave resonator.

39. The multiplexer according to claim 36, wherein
the transmission filter includes the surface acoustic wave filter;
the at least one parallel-arm resonator includes a plurality of parallel-arm resonators connected in parallel between a path connecting the antenna connection terminal and the PA connection terminal and ground; and
the parallel-arm resonator closest to the antenna connection terminal among the plurality of parallel-arm resonators includes the surface acoustic wave resonator.

40. The multiplexer according to claim 36, wherein
the reception filter includes the surface acoustic wave filter;
the at least one series-arm resonator includes a plurality of series-arm resonators connected in series between the antenna connection terminal and the LNA connection terminal; and
the series-arm resonator closest to the antenna connection terminal among the plurality of series-arm resonators includes the surface acoustic wave resonator.

41. The multiplexer according to claim 36, wherein
the reception filter includes the surface acoustic wave filter;
the at least one parallel-arm resonator includes a plurality of parallel-arm resonators connected in parallel between a path connecting the antenna connection terminal and the LNA connection terminal and ground; and
the parallel-arm resonator closest to the antenna connection terminal among the plurality of parallel-arm resonators includes the surface acoustic wave resonator.

42. A surface acoustic wave resonator comprising:
a substrate including a piezoelectric layer;
at least one electrode on the substrate and including an interdigital transducer (IDT) electrode; and
a dielectric film on the at least one electrode; wherein
the at least one electrode includes a plurality of electrode fingers arranged along a first axis on the substrate and each extending along a second axis perpendicular or substantially perpendicular to the first axis;
an average of a thickness of the dielectric film on an electrode finger of the plurality of electrode fingers in a first sub-region and an average of a thickness of the dielectric film on an electrode finger of the plurality of electrode fingers in a third sub-region are each larger than an average of a thickness of the dielectric film on an electrode finger of the plurality of electrode fingers in a second sub-region;
the first sub-region, the second sub-region, and the third sub-region are obtained by equally dividing, in a direction of the first axis, a region in which the plurality of electrode fingers are located on the substrate; and
the second sub-region is located between the first sub-region and the third sub-region.
